(19) United States
(12) Patent Application Publication
(10) Pub. No.: US 2025/0386611 A1
(43) Pub. Date: Dec. 18, 2025

(54) IMAGE SENSOR

(71) Applicant: Samsung Electronics Co., Ltd., Suwon-si (KR)

(72) Inventors: Junghyun KIM, Suwon-si (KR); Bumsuk KIM, Suwon-si (KR); Jonghoon PARK, Suwon-si (KR); Yun Ki LEE, Suwon-si (KR)

(73) Assignee: Samsung Electronics Co., Ltd., Suwon-si (KR)

(21) Appl. No.: 19/240,919

(22) Filed: Jun. 17, 2025

(30) Foreign Application Priority Data
Jun. 18, 2024 (KR) 10-2024-0079004

(51) Int. Cl. H10F 39/00

(52) U.S. Cl. CPC H10F 39/8063; H10F 39/8053; H10F 39/807; H10F 39/811

(57) ABSTRACT

An image sensor including a substrate having first and second surfaces, the second surface opposite the first surface; a first deep trench isolation layer in the substrate and defining pixel region groups, each pixel region group having a pair of pixel regions; a second deep trench isolation layer between the pair of pixel regions of each pixel region group; photoelectric conversion areas in each pixel region; and a lens array on the second surface and composed of two-dimensionally arranged microlenses. Each microlens having a shape, in plan view, with a long axis and a short axis, the short axis being substantially perpendicular to the long axis and shorter than the long axis. The microlenses covering each pixel region group, and a width of at least a first portion of the second deep trench isolation layer being smaller than a width of the first deep trench isolation layer.

### CROSS-REFERENCE TO RELATED APPLICATION

This application claims benefit of priority to Korean Patent Application No. 10-2024-0079004, filed on Jun. 18, 2024, in the Korean Intellectual Property Office, the disclosure of which is incorporated herein by reference in its entirety.

### BACKGROUND

The present inventive concepts relate to image sensors.

An image sensor is a semiconductor element that converts an optical image into an electrical signal. The image sensor can be classified into a charge coupled device (CCD) type and a complementary metal oxide semiconductor (CMOS) type. The CMOS type image sensor is abbreviated as a CIS (CMOS Image Sensor). The CMOS type image sensor is provided with a plurality of pixels arranged two-dimensionally. Each of the pixels includes a photodiode (PD) as a photoelectric conversion element, and an isolation layer is formed between the photoelectric conversion elements to separate the photoelectric conversion elements from each other. The isolation layer can exhibit a light absorption effect depending on the material. When there is light absorption in a portion of a light incident side, the amount of light incident on the photoelectric conversion elements may decrease, thereby reducing the sensitivity of the image sensor.

### SUMMARY

Some example embodiments of the present inventive concepts are directed towards providing an image sensor that can improve photoelectric conversion efficiency by reducing, minimizing, or preventing light loss.

An image sensor according to some example embodiments may include a substrate including a first surface and a second surface opposite to the first surface; a first deep trench isolation layer in the substrate, the first deep trench isolation layer defining pixel region groups, each of the pixel region groups including a pair of pixel regions; a second deep trench isolation layer between the pair of pixel regions of each of the pixel region groups; photoelectric conversion areas in each of the pixel regions; and a lens array on the second surface of the substrate and composed of two-dimensionally arranged microlenses. Each of the microlenses of the lens array having a shape, in plan view, with a long axis and a short axis, the short axis being substantially perpendicular to the long axis and shorter than the long axis. The microlenses covering each of the pixel region groups, and a width of at least a first portion of the second deep trench isolation layer being smaller than a width of the first deep trench isolation layer.

According to some example embodiments, the pixel regions of each of the pixel region groups are arranged in a direction parallel to the long axis of a microlens corresponding to each of the pixel region groups, each of the pixel regions has a first width in the direction parallel to the long axis and a second width in a direction parallel to the short axis, and the second width may be less than twice the first width.

According to some example embodiments, the first width may be 80% to 120% of the second width.

According to some example embodiments, the first deep trench isolation layer may include a first buried conductive pattern and a first insulating liner, the first insulating liner being between the first buried conductive pattern and the substrate, the second deep trench isolation layer may include a second buried conductive pattern and a second insulating liner, the second insulating liner being between the second buried conductive pattern and the substrate, and a first width of the second buried conductive pattern of at least the first portion of the second deep trench isolation layer may be smaller than a width of the first buried conductive pattern of the first deep trench isolation layer.

According to some example embodiments, a second width of the second buried conductive pattern of a second portion of the second deep trench isolation layer is substantially same as the width of the first buried conductive pattern of the first deep trench isolation layer.

According to some example embodiments, a second width of the second buried conductive pattern of a second portion of the second deep trench isolation layer may be greater than the first width of the second buried conductive pattern of at least the first portion of the second deep trench isolation layer, and the second width of the second buried conductive pattern of the second portion of the second deep trench isolation layer may be smaller than the width of the first buried conductive pattern of the first deep trench isolation layer.

According to some example embodiments, the first buried conductive pattern and the second buried conductive pattern may include at least one of doped polysilicon or a metal.

According to some example embodiments, at least the first portion of the second deep trench isolation layer may include an insulating material and does not include a conductive material.

According to some example embodiments, the width of at least the first portion of the second deep trench isolation layer may be 40% to 80% of the width of the first deep trench isolation layer.

According to some example embodiments, from the plan view, a length of at least the first portion of the second deep trench isolation layer may be 10% or more of a total length of the second deep trench isolation layer.

According to some example embodiments, the long axes of the microlenses may be parallel to each other.

According to some example embodiments, at least one of the long axes of the microlenses may be substantially perpendicular to at least another one of the long axes of the microlenses.

According to some example embodiments, the image sensor may further include a color filter array between the second surface of the substrate and the lens array, the color filter array including a plurality of color filters, a color of a color filter under at least one of the microlenses may differ from a color of a color filter under at least another one of the microlenses.

According to some example embodiments, each of the color filters may cover a pair of pixel region groups adjacent to each other, and the pixel regions of the pair of pixel region groups may be arranged in a 2×2 matrix.

According to some example embodiments, each of the color filters may cover eight pixel region groups adjacent to each other, and the pixel regions of the eight pixel region groups may be arranged in a 4×4 matrix.

An image sensor according to some example embodiments may include a substrate including a first surface and a second surface opposite to the first surface; a first deep trench isolation layer in the substrate, the first deep trench isolation layer defining pixel region groups, each of the pixel region groups including a pair of pixel regions; a second deep trench isolation layer between the pair of pixel regions of each of the pixel region groups; photoelectric conversion areas in each of the pixel regions; and a lens array on the second surface of the substrate and composed of two-dimensionally arranged microlenses. Each of the microlenses of the lens array may have a shape, in plan view, with a long axis and a short axis, the short axis may be substantially perpendicular to the long axis and shorter than the long axis. The microlenses may cover each of the pixel region groups. The pixel regions of each of the pixel region groups may be arranged in a direction parallel to the long axis of a microlens corresponding to each of the pixel region groups. Each of the pixel regions may have a first width in the direction parallel to the long axis and a second width in a direction parallel to the short axis, the first width may be 80% to 120% of the second width, and a width of at least a first portion of the second deep trench isolation layer may be smaller than a width of the first deep trench isolation layer.

According to some example embodiments, the first deep trench isolation layer may include a first buried conductive pattern, and the second deep trench isolation layer may include a second buried conductive pattern, and a first width of the second buried conductive pattern of at least the first portion of the second deep trench isolation layer may be smaller than a width of the first buried conductive pattern of the first deep trench isolation layer.

According to some example embodiments, at least the first portion of the second deep trench isolation layer may include an insulating material and does not include a conductive material.

An image sensor according to some example embodiments may include a substrate including a first surface and a second surface opposite to the first surface; a first deep trench isolation layer in the substrate, the first deep trench isolation layer defining pixel region groups, each of the pixel region groups including a pair of pixel regions; a second deep trench isolation layer between the pair of pixel regions; photoelectric conversion areas in each of the pixel regions; and a lens array on the second surface of the substrate and composed of two-dimensionally arranged microlenses. Each of the microlenses of the lens array may have a shape, in plan view, with a long axis and a short axis, the short axis may be substantially perpendicular to the long axis and shorter than the long axis, the microlenses may cover each of the pixel region groups. In the plan view, the second deep trench isolation layer may have first and second portions that are spaced apart from each other in a direction parallel to the short axis of the microlenses, and the pair of pixel regions may be connected to each other without an interface between the first portion and the second portion of the second deep trench isolation layer.

According to some example embodiments, the pixel regions of each of the pixel region groups may be arranged in a direction parallel to the long axis of a microlens corresponding to each of the pixel region groups, each of the pixel regions may have a first width in the direction parallel to the long axis and a second width in the direction parallel to the short axis, and the second width may be less than twice the first width.

### BRIEF DESCRIPTION OF DRAWINGS

FIG. 1 is a block diagram of an image sensor according to some example embodiments.

FIG. 2 is a circuit diagram of pixels of an image sensor according to some example embodiments.

FIG. 3 is a plan view showing an image sensor according to some example embodiments.

FIG. 4A is a cross-sectional view taken along line A-A′ of FIG. 3 according to some example embodiments.

FIG. 4B is a cross-sectional view taken along line B-B′ of FIG. 3 according to some example embodiments.

FIG. 5 is a plan view showing an image sensor according to some example embodiments.

FIG. 6 is a cross-sectional view taken along line A-A′ of FIG. 5 according to some example embodiments.

FIG. 7 is a plan view showing an image sensor according to some example embodiments.

FIG. 8 is a cross-sectional view taken along line A-A′ of FIG. 7 according to some example embodiments.

FIG. 9 is a plan view showing an image sensor according to some example embodiments.

FIG. 10 is a plan view showing an image sensor according to some example embodiments.

FIGS. 11A to 11G are cross-sectional views corresponding to line A-A′ of FIG. 3 to show a manufacturing method of an image sensor according to some example embodiments.

FIG. 12 is a plan view showing an image sensor according to some example embodiments.

FIG. 13 is a plan view showing an image sensor according to some example embodiments.

FIG. 14 is a cross-sectional view taken along line A-A′ of FIG. 13 according to some example embodiments.

FIG. 15 is a plan view showing an image sensor according to some example embodiments.

FIG. 16 is a cross-sectional view taken along line A-A′ of FIG. 15 according to some example embodiments.

FIG. 17 is a cross-sectional view taken along line B-B′ of FIG. 15 according to some example embodiments.

FIG. 18 is a cross-sectional view showing an image sensor according to some example embodiments.

FIG. 19 is a cross-sectional view showing an image sensor according to some example embodiments.

### DETAILED DESCRIPTION

Hereinafter, some example embodiments of the present inventive concepts will be described in more detail with reference to the accompanying drawings.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof. Additionally, elements and/or properties thereof (e.g., structures, surfaces, directions, or the like) that are “substantially perpendicular” or “substantially parallel” with regard to other elements and/or properties thereof will be understood to be “perpendicular” or “parallel” with regard to the other elements and/or properties thereof within manufacturing tolerances and/or material tolerances and/or have a deviation in magnitude and/or angle from “perpendicular,” or “parallel,” or the like with regard to the other elements and/or properties thereof that is equal to or less than 10% (e.g., a tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

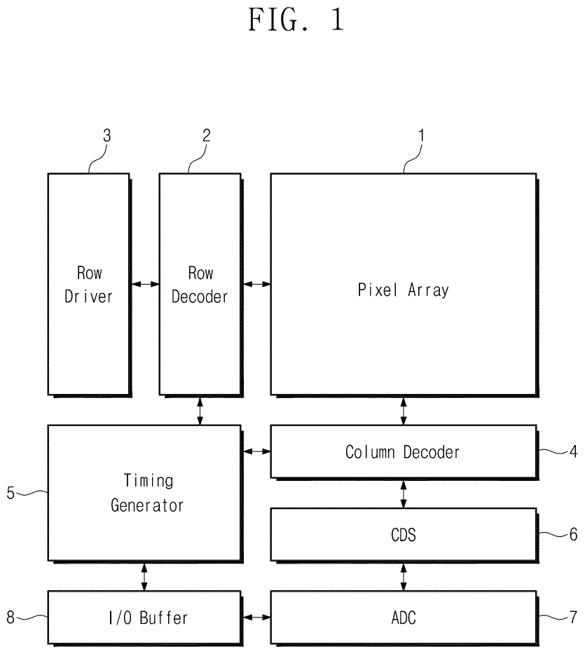

FIG. 1 is a block diagram of image sensors according to some example embodiments.

Referring to FIG. 1, an image sensor according to some example embodiments may include a pixel array 1, a row decoder 2, a row driver 3, a column decoder 4, a timing generator 5, a correlated double sampler (CDS) 6, an analog to digital converter (ADC) 7, and an input/output buffer (I/O buffer) 8.

The pixel array 1 may include a plurality of pixels arranged two-dimensionally, and the pixels may convert optical signals into electrical signals. The pixel array 1 may be driven by a plurality of driving signals (e.g., a pixel selection signal, a reset signal, and/or a charge transfer signal) transmitted or sent from the row driver 3. The converted electrical signals may be provided to the correlated double sampler 6.

The row driver 3 may provide, transfer, or send the plurality of driving signals to the pixel array 1 for driving the plurality of pixels based on decoded results from the row decoder 2. When the pixels are arranged in a matrix form, the driving signals may be provided in a row unit.

The timing generator 5 may provide, transfer, or send a timing signal and a control signal to the row decoder 2 and the column decoder 4.

The correlated double sampler 6 may receive the electrical signals generated from the pixel array 1 and may hold or store and sample the received signals. The correlated double sampler 6 may double-sample a specific, or alternatively desired, noise level and a signal level caused by an electrical signal to output a difference level corresponding to the difference between the noise level and the signal level.

The analog to digital converter 7 may convert an analog signal corresponding to the difference level output from the correlated double sampler 6 into a digital signal and may output the digital signal.

The input/output buffer 8 may latch the digital signals and sequentially output the latched signals to an image signal processor (not shown) based on the decoded results from the column decoder 4.

According to some example embodiments, the image sensor may further include an autofocus circuit (not shown) capable of performing an autofocus function. The autofocus circuit may receive autofocus signals generated from a pair of adjacent pixels in the pixel array 1 and may generate a lens control signal using the autofocus signals. The autofocus circuit may transmit, transfer, or send the lens control signal to a lens driving unit (not shown) to drive an objective lens. Therefore, the focus of an optical system (not shown) including the image sensor may be adjusted.

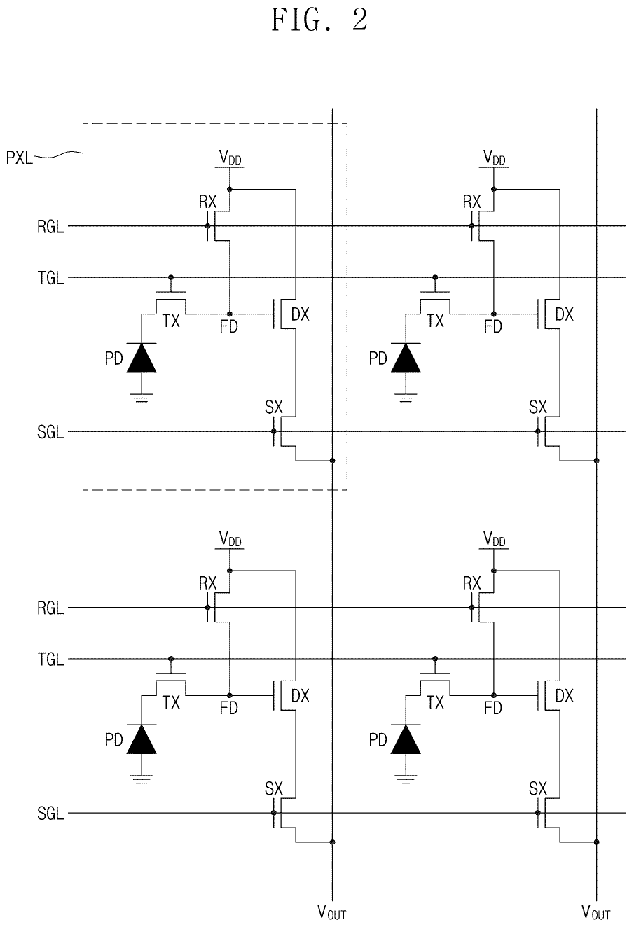

FIG. 2 is a circuit diagram of pixels of an image sensor according some example embodiments.

Referring to FIG. 2, a pixel array may include a plurality of pixels PXL, and the pixels PXL may be arranged in a matrix form. Each of the pixels PXL may include pixel transistors, and the pixel transistors may include a transfer transistor TX and logic transistors RX, SX, and DX. The logic transistors RX, SX, and DX may include a reset transistor RX, a selection transistor SX, and a source follower transistor DX. A transfer gate of the transfer transistor TX may be connected to a transfer gate line TGL. Each of the pixels PXL may further include a photoelectric conversion element PD and a floating diffusion region FD.

The photoelectric conversion element PD may generate and accumulate photocharges in proportion to an amount of light incident from outside. The photoelectric conversion element PD may include a photodiode, a phototransistor, a photogate, a pinned photodiode, or a combination thereof, but example embodiments are not limited thereto. The transfer transistor TX may transfer the photocharges generated from the photoelectric conversion element PD to the floating diffusion region FD. The floating diffusion region FD may receive and cumulatively store the photocharges generated from the photoelectric conversion element PD.

A gate of the source follower transistor DX may be connected to the floating diffusion region FD. A drain electrode of the source follower transistor DX may be connected to a power terminal VDD that can receive a power voltage. The source follower transistor DX may be controlled according to the amount of photocharges accumulated in the floating diffusion region FD.

The reset transistor RX may periodically reset the charges accumulated in the floating diffusion region FD. A gate of the reset transistor RX may be connected to a reset gate line RGL. A source electrode of the reset transistor RX may be connected to the floating diffusion region FD, and a drain electrode of the reset transistor RX may be connected to the power terminal VDD. When the reset transistor RX is turned on, the power voltage of the power terminal VDD may be applied to the floating diffusion region FD through the reset transistor RX. For example, when the reset transistor RX is turned on, the charges accumulated in the floating diffusion region FD may be discharged by the power voltage, thereby resetting the floating diffusion region FD.

The source follower transistor DX may serve as a source follower buffer amplifier. The source follower transistor DX may amplify a potential change in the floating diffusion region FD and output the amplified potential change to an output line VOUT.

A gate of the selection transistor SX may be connected to a selection gate line SGL. A drain electrode of the selection transistor SX may be connected to the source electrode of the source follower transistor DX, and a source electrode of the selection transistor SX may be connected to the output line VOUT. The selection transistors SX of the pixels PXL to be readout in row units may be selected by a selection signal applied through a corresponding selection gate line SGL. When the selection transistor SX is turned on, the potential change amplified by the source follower transistor DX may be output to the output line VOUT through the selection transistor SX.

As shown in FIG. 2, in some example embodiments, each of the pixels PXL may include the pixel transistors. Alternatively, in some example embodiments, some pixels PXL adjacent to each other may share at least one of the pixel transistors (for example, at least one of the logic transistors RX, SX, and DX).

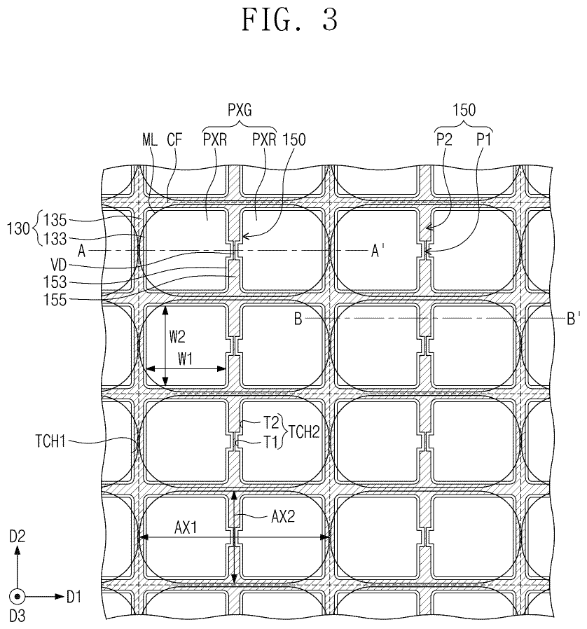

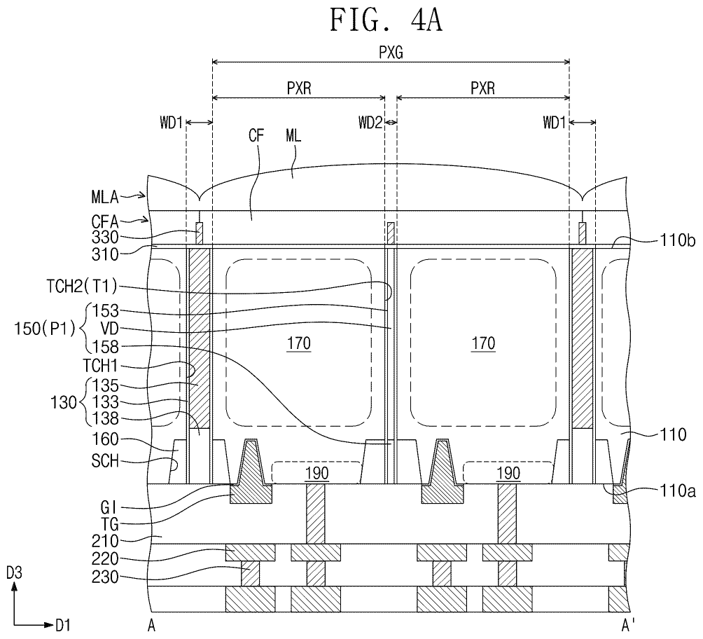

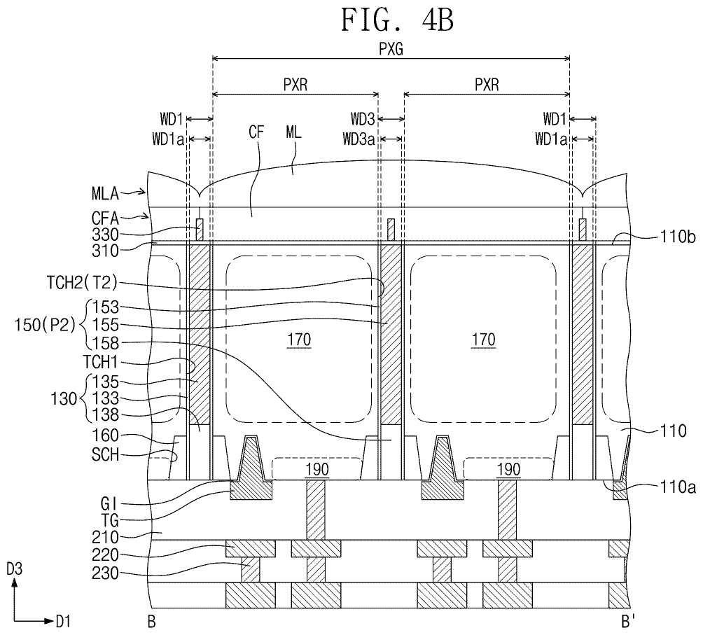

FIG. 3 is a plan view showing an image sensor according to some example embodiments, FIG. 4A is a cross-sectional view taken along line A-A′ of FIG. 3 according to some example embodiments, and FIG. 4B is a cross-sectional view taken along line B-B′ of FIG. 3 according to some example embodiments.

Referring to FIGS. 3, 4A, and 4B, the image sensor according to some example embodiments may include a substrate 110, a first deep trench isolation layer 130, a second deep trench isolation layer 150, a shallow trench isolation layer 160, a photoelectric conversion area 170, an upper insulating film 310, a grid pattern 330, a color filter CF, and a microlens ML.

The substrate 110 may have a first surface 110a and a second surface 110b that face each other. For example, the first surface 110a of the substrate 110 may be a front surface, and the second surface 110b of the substrate 110 may be a back surface. Light may be incident on the second surface 110b of the substrate 110. Accordingly, the second surface 110b may be a light incident surface.

The substrate 110 may be a semiconductor substrate or an SOI (Silicon on Insulator) substrate. The substrate 110 may include, for example, a silicon substrate, a germanium substrate, or a silicon-germanium substrate. The substrate 110 may include impurities of a first conductivity type. Accordingly, the substrate 110 may have the first conductivity type. The impurities of the first conductivity type may be a group 3 element. For example, the impurities of the first conductivity type may be p-type impurities such as boron (B).

A first deep trench TCH1 may be formed in the substrate 110 to define pixel region groups PXG, and the first deep trench isolation layer 130 may be provided in the first deep trench TCH1. The first deep trench isolation layer 130 may surround each of the pixel region groups PXG from a plan view. The pixel region groups PXR may be arranged two-dimensionally.

Each of the pixel region groups PXG may have a pair of pixel regions PXR. A second deep trench TCH2 may be formed in the substrate 110 between the pair of pixel regions PXR, and the second deep trench isolation layer 150 may be provided in the second deep trench TCH2. For example, each of the pixel regions PXR may be defined by the first and second deep trench isolation layers 130 and 150. According to some example embodiments, each of the pixel regions PXR may be a portion of the substrate 110 surrounded by the first and second deep trench isolation layers 130 and 150 from a plan view. The pixel regions PXR of the pixel region groups PXG may be arranged in a matrix form along a first and a second directions D1 and D2. The first and second directions D1 and D2 may be parallel to the second surface 110b of the substrate 110 and may intersect each other. For example, the first and second directions D1 and D2 may be perpendicular to each other. The first and second deep trench isolation layers 130 and 150 may extend in a direction (e.g., a third direction D3) perpendicular to the second surface 110b of the substrate 110.

The photoelectric conversion area 170 may be provided in each of the pixel regions PXR. The photoelectric conversion area 170 may be disposed between the first surface 110a and the second surface 110b of the substrate 110. In some example embodiments, the photoelectric conversion area 170 may be spaced apart from the first surface 110a and the second surface 110b of the substrate 110. The photoelectric conversion area 170 may be an area doped with impurities of a second conductivity type. The second conductivity type may be a conductivity type opposite to the first conductivity type. In some example embodiments, the impurities of the second conductivity type may include a group V element. For example, the impurities of the second conductivity type may include n-type impurities such as phosphorus and/or arsenic. The photoelectric conversion area 170 having the second conductivity type may be PN-junctioned with the pixel region PXR having the first conductivity type to configure a photoelectric conversion element (e.g., a photodiode).

A shallow trench SCH may be formed in the substrate 110 to define active areas in the pixel regions PXR, and the shallow trench isolation layer 160 may fill the shallow trench SCH. The shallow trench SCH may be recessed into the substrate 110 from the first surface 110a of the substrate 110. For example, the shallow trench isolation layer 160 may be adjacent to the first surface 110a of the substrate 110. In some example embodiments, one or more active areas may be defined in each of the pixel regions PXR.

A transfer gate TG may be disposed on the first surface 110a of the substrate 110 and may be disposed on corresponding active area of each of the pixel regions PXR. A gate dielectric layer GI may be disposed between the transfer gate TG and the corresponding active area. In some example embodiments, the transfer gate TG may fill a gate trench recessed into the corresponding active area from the first surface 110a. For example, the gate dielectric layer GI may extend and be disposed between the transfer gate TG and an inner surface of the gate trench. When the transfer gate TG fills the gate trench, the transfer transistor TX including the transfer gate TG may be a vertical channel type transistor.

The floating diffusion region 190 may be provided in the corresponding active area on one side of the transfer gate TG. The floating diffusion region 190 may be an area doped with impurities. The floating diffusion region 190 may include impurities of the second conductivity type. When light is incident into the photoelectric conversion area 170, photocharges may be generated and accumulated in the photoelectric conversion area 170. When the transfer transistor TX is turned on, the accumulated photocharges may be transferred to the floating diffusion region 190 through the transfer transistor TX. The floating diffusion region 190 may correspond to the floating diffusion region FD of FIG. 2.

According to some example embodiments, the logic transistors RX, SX, and DX of the pixel PXL of FIG. 2 may be provided on different active areas of each of the pixel regions PXR. For example, the pixel PXL of FIG. 2 may be implemented in and on each of the pixel regions PXR. However, example embodiments of the present inventive concepts are not limited thereto. In some example embodiments, at least one of the logic transistors RX, SX, and DX may be formed to be shared by adjacent pixels. In some example embodiments, at least one of the logic transistors RX, SX, and DX may be formed on a different substrate.

A width WD2 of at least one portion of the second deep trench isolation layer 150 may be smaller than a width WD1 of the first deep trench isolation layer 130. For example, a width WD2 of at least a first portion of the second deep trench isolation layer 150 may be smaller than a width WD1 of the first deep trench isolation layer 130. In some example embodiments, one portion P1 of the second deep trench isolation layer 150 is provided in one area T1 of the second deep trench TCH2, and the other portion P2 of the second deep trench isolation layer 150 is provided in the other area T2 of the second deep trench TCH2. Here, the width WD2 of one portion P1 of the second deep trench isolation layer 150 may be smaller than the width WD1 of the first deep trench isolation layer 130. The width WD2 of one portion P1 of the second deep trench isolation layer 150 may be smaller than the width WD3 of the other portion P2 of the second deep trench isolation layer 150. For example, the first portion P1 of the second deep trench isolation layer 150 may be provided in a first area T1 of the second deep trench TCH2, and a second portion P2 of the second deep trench isolation layer 150 may be provided in a second area T2 of the second deep trench TCH2. The width WD2 of the first portion P1 of the second deep trench isolation layer 150 may be smaller than the width WD1 of the first deep trench isolation layer 130. The width WD2 of the first portion P1 of the second deep trench isolation layer 150 may be smaller than a width WD3 of the second portion P2 of the second deep trench isolation layer 150. In some example embodiments, the above-described widths WD1, WD2, and WD3 may refer to the widths of upper ends of the first and second deep trench isolation layers 130 and 150. The upper ends of the first and second deep trench isolation layers 130 and 150 may be adjacent to the second surface 110b of the substrate 110. For example, the width WD2 of the upper end of one portion P1 (e.g., the first portion P1) of the second deep trench isolation layer 150 may be smaller than the width WD1 of the upper end of the first deep trench isolation layer 130 and the width WD3 of the upper end of the other portion P2 (e.g., the second portion P2) of the second deep trench isolation layer 150.

In some example embodiments, as shown in FIGS. 4A and 4B, the width of the upper end of each of the first and second deep trench isolation layers 130 and 150 may be the same or substantially the same as a width of a lower end of each of the first and second deep trench isolation layers 130 and 150. For example, the width WD1 of the upper end of the first deep trench isolation layer 130 and the widths WD2 and WD3 of the second deep trench isolation layer 150 may be the same or substantially the same as a width of a lower end of each of the first and second deep trench isolation layers 130 and 150. However, example embodiments of the present inventive concepts are not limited thereto. In some example embodiments, the width of the upper end of each of the first and second deep trench isolation layers 130 and 150 may be smaller than the width of the lower end of each of the first and second deep trench isolation layers 130 and 150. Alternatively, in some example embodiments, the width of the upper end of each of the first and second deep trench isolation layers 130 and 150 may be greater than the width of the lower end of each of the first and second deep trench isolation layers 130 and 150. For example, when the width of the upper end of each of the first and second deep trench isolation layers 130 and 150 is different from the width of the lower end of each of the first and second deep trench isolation layers 130 and 150, side surfaces of each of the first and second deep trench isolation layers 130 and 150 may be inclined.

Hereinafter, unless otherwise specified, the widths of the first and second deep trench isolation layers 130 and 150 may be understood as the widths of the upper ends of the first and second deep trench isolation layers 130 and 150.

In some example embodiments, the first deep trench isolation layer 130 may have a uniform or substantially uniform width from a plan view (e.g., when viewed from a plan view). However, example embodiments of the present inventive concepts are not limited thereto. In some example embodiments, the first deep trench isolation layer 130 may have a non-uniform width from a plan view (e.g., when viewed from a plan view). For example, the width WD2 of one portion P1 (e.g., the first portion P1) of the second deep trench isolation layer 150 may be smaller than a minimum width of the first deep trench isolation layer 130.

In some example embodiments, the width WD3 of the other portion P2 (e.g., the second portion P2) of the second deep trench isolation layer 150 may be the same or substantially the same as the width WD1 of the first deep trench isolation layer 130. However, example embodiments of the present inventive concepts are not limited thereto. In some example embodiments, the width WD3 of the other portion P2 (e.g., the second portion P2) of the second deep trench isolation layer 150 may be greater than the width WD2 of one portion P1 (e.g., the first portion P1) of the second deep trench isolation layer 150 and smaller than the width WD1 of the first deep trench isolation layer 130.

As shown in FIG. 3, one portion P1 (e.g., the first portion P1) of the second deep trench isolation layer 150 may correspond to a middle portion of the second deep trench isolation layer 150, and the other portion P2 (e.g., the second portion P2) of the second deep trench isolation layer 150 may correspond to both edge portions of the second deep trench isolation layer 150. The other portion P2 (e.g., the second portion P2) of the second deep trench isolation layer 150 may be connected to the first deep trench isolation layer 130. However, example embodiments of the present inventive concepts are not limited thereto. In some example embodiments, one portion P1 (e.g., the first portion P1) of the second deep trench isolation layer 150 having the relatively small width WD2 may be provided at a different location in the second deep trench isolation layer 150.

According to some example embodiments, the first and second deep trench isolation layers 130 and 150 may pass through the substrate 110 and the shallow trench isolation layer 160. The first deep trench isolation layer 130 may include a first insulating liner 133, a first buried conductive pattern 135, and a first capping insulating pattern 138.

The first insulating liner 133 may be provided along the inner side surface of the first deep trench TCH1. The first insulating liner 133 may conformally cover the inner side surface of the first deep trench TCH1. The first insulating liner 133 may be provided between the substrate 110 and the first buried conductive pattern 135 to electrically insulate the substrate 110 and the first buried conductive pattern 135 from each other. In some example embodiments, the first insulating liner 133 may be provided between the first capping insulating pattern 138 and the shallow trench isolation layer 160.

The first insulating liner 133 may include an insulating material, such as a silicon-based insulating material (e.g., a silicon nitride (Si3N4), a silicon oxide (SiO₂), a silicon oxynitride, and/or a silicon carbon nitride (SiCN)) and/or a high dielectric metal oxide (e.g., a hafnium oxide (HfOx), a zirconium oxide (ZrO2), and/or an aluminum oxide (Al2O3), etc.), but example embodiments are not limited thereto.

The first insulating liner 133 is shown as a single layer in FIG. 4A, but example embodiments are not limited thereto. In some example embodiments, the first insulating liner 133 may include a plurality of stacked layers, and the stacked layers may include different materials from each other.

The first insulating liner 133 may have a smaller refractive index than the substrate 110. Accordingly, in some example embodiments, crosstalk between pixels may be reduced or minimized.

The first buried conductive pattern 135 may be formed of a conductive material (e.g., doped poly-silicon or a metal). The doped poly-silicon may include the impurities of the first conductivity type (e.g., P-type) or the impurities of the second conductivity type (e.g., N-type). For example, the first buried conductive pattern 135 may include poly-silicon doped with boron (B), or poly-silicon doped with phosphorus (P) or arsenic (As).

According to some example embodiments, when the first buried conductive pattern 135 includes a metal, the first buried conductive pattern 135 may include copper, tungsten, aluminum, and/or titanium. However, example embodiments of the present inventive concepts are not limited thereto. In some example embodiments, the first buried conductive pattern 135 may include another conductive material, for example, at least one of various other metals, an organic/inorganic material doped with an impurity, or a combination thereof. For example, the other conductive material may include a conductive metal oxide, a metal grid, a random metal network, a carbon nanotube, a graphene, a nanowire mesh, an ultra-thin metal film, and/or a conductive polymer.

According to some example embodiments, when the first buried conductive pattern 135 is formed in the first deep trench TCH1, a void such as an air gap may be formed in the first buried conductive pattern 135.

The first capping insulating pattern 138 may cover a lower end of the first buried conductive pattern 135 and may be adjacent to the first surface 110a of the substrate 110. The first capping insulating pattern 138 may include an insulating material, such as a silicon-based insulating material (e.g., a silicon nitride (Si3N4), a silicon oxide (SiO2), a silicon oxynitride, and/or a silicon carbon nitride (SiCN)) and/or a high dielectric metal oxide (e.g., a hafnium oxide (HfOx), a zirconium oxide (ZrO2), and/or an aluminum oxide (Al2O3), etc.).

According to some example embodiments, the second deep trench isolation layer 150 may include a second insulating liner 153, a second buried conductive pattern 155, and a second capping insulating pattern 158.

The second insulating liner 153 may be provided along an inner side surface of the second deep trench TCH2. The second insulating liner 153 may conformally cover the inner side surface of the second deep trench TCH2. The second insulating liner 153 may be provided between the substrate 110 and the second buried conductive pattern 155 to electrically insulate the substrate 110 and the second buried conductive pattern 155 from each other. In some example embodiments, the second insulating liner 153 may be provided between the second capping insulating pattern 158 and the shallow trench isolation layer 160.

In some example embodiments, one portion P1 (e.g., the first portion P1) of the second deep trench isolation layer 150 having the relatively small width WD2 may not include the second buried conductive pattern 155 as shown in FIG. 4A, and the other portion P2 (e.g., the second portion P2) of the second deep trench isolation layer 150 having the relatively great width WD3 may include the second buried conductive pattern 155 as shown in FIG. 4B. In some example embodiments, one portion P1 (e.g., the first portion P1) of the second deep trench isolation layer 150 may have a void VD such as an air gap.

The second insulating liner 153 may include an insulating material, such as a silicon-based insulating material (e.g., a silicon nitride (Si3N4), a silicon oxide (SiO₂), a silicon oxynitride, and/or a silicon carbon nitride (SiCN)) and/or a high dielectric metal oxide (e.g., a hafnium oxide (HfOx), a zirconium oxide (ZrO2), and/or an aluminum oxide (Al2O3), etc.).

The second insulating liner 153 is shown as a single layer in FIGS. 4A and 4B, but example embodiments are not limited thereto. In some example embodiments, the second insulating liner 153 may include a plurality of stacked layers, and the stacked layers may include different materials from each other.

The second insulating liner 153 may have a smaller refractive index than the substrate 110. Accordingly, in some example embodiments, crosstalk between pixels may be reduced or minimized.

The second buried conductive pattern 155 may be formed of a conductive material (e.g., doped poly-silicon or a metal). The doped poly-silicon may include the impurities of the first conductivity type (e.g., P-type) or the impurities of the second conductivity type (e.g., N-type). For example, the second buried conductive pattern 155 may include poly-silicon doped with boron (B), or poly-silicon doped with phosphorus (P) or arsenic (As).

According to some example embodiments, when the second buried conductive pattern 155 includes a metal, the second buried conductive pattern 155 may include copper, tungsten, aluminum, and/or titanium. However, example embodiments of the present inventive concepts are not limited thereto. In some example embodiments, the second buried conductive pattern 155 may include another conductive material, for example, at least one of various other metals, an organic/inorganic material doped with an impurity, or a combination thereof. For example, the other conductive material may include a conductive metal oxide, a metal grid, a random metal network, a carbon nanotube, a graphene, a nanowire mesh, an ultra-thin metal film, and/or a conductive polymer.

According to some example embodiments, when the second buried conductive pattern 155 is formed in the second deep trench TCH2 (for example, in the other area T2 (e.g., the second area T2) of the second deep trench TCH2), a void such as an air gap may be formed in the second buried conductive pattern 155.

The second capping insulating pattern 158 may be provided in a lower area of the second deep trench TCH2. The second capping insulating pattern 158 may be adjacent to the first surface 110a of the substrate 110. In some example embodiments, one portion P1 (e.g., the first portion P1) of the second deep trench isolation layer 150 may include the second insulating liner 153, the second capping insulating pattern 158, and the void VD, and the other portion P2 (e.g., the second portion P2) of the second deep trench isolation layer 150 may include the second insulating liner 153, the second buried conductive pattern 155, and the second capping insulating pattern 158.

The second capping insulating pattern 158 may include an insulating material, such as a silicon-based insulating material (e.g., a silicon nitride (Si3N4), a silicon oxide (SiO2), a silicon oxynitride, and/or a silicon carbon nitride (SiCN)) and/or a high dielectric metal oxide (e.g., a hafnium oxide (HfOx), a zirconium oxide (ZrO2), and/or an aluminum oxide (Al2O3), etc.).

The shallow trench isolation layer 160 may include at least one of various insulating materials. For example, the shallow trench isolation layer 160 may include at least one of a silicon oxide film, a silicon nitride film, or a silicon oxynitride film.

In some example embodiments, the first insulating liner 133 may be formed of the same material as the second insulating liner 153, the first buried conductive pattern 135 may be formed of the same material as the second buried conductive pattern 155, and the first capping insulating pattern 138 may be formed of the same material as the second capping insulating pattern 158.

As shown in FIGS. 4A and 4B, interfaces may exist between the shallow trench isolation layer 160 and the insulating liners 133 and 153, between the first insulating liner 133 and the first capping insulating pattern 138, and between the second insulating liner 153 and the second capping insulating pattern 158. Alternatively, in some example embodiments, when the shallow trench isolation layer 160, the insulating liners 133 and 153, and the capping insulating patterns 138 and 158 are formed of the same material, the interfaces may not be visible.

Interlayer insulating films 210 may be disposed on the first surface 110a of the substrate 110 to cover the pixel transistors, and wirings 220 and contact plugs 230 may be disposed in the interlayer insulating films 210. To implement the pixel PXL of FIG. 2, in some example embodiments, the wirings 220 and contact plugs 230 may be properly connected to the floating diffusion region 190 and the gates and source/drain areas of the pixel transistors. Each of the interlayer insulating films 210 may be formed of an insulating material (e.g., a silicon oxide, a silicon nitride, and/or a silicon oxynitride), and the wirings 220 and contact plugs 230 may be formed of a conductive material (e.g., a metal, a metal nitride, and/or a metal silicide).

The upper insulating film 310 may be provided on the second surface 110b of the substrate 110. The upper insulating film 310 may cover the second surface 110b of the substrate 110 and upper surfaces of the first and second deep trench isolation layers 130 and 150. The upper insulating film 310 may be formed of a transparent insulating material. The upper insulating film 310 may have a single-layer structure or a multi-layer structure.

In some example embodiments, the upper insulating film 310 may perform a function as an antireflective layer and/or a function as a fixed charge layer. In some example embodiments, when the upper insulating film 310 is used as the antireflective layer, the upper insulating film 310 may include, for example, at least one of a hafnium oxide (HfOx), a zirconium oxide (ZrO2), or an aluminum oxide (Al2O3). For example, the upper insulating film 310 may mitigate or prevent reflection of light so that light incident on the second surface 110b of the substrate 110 may smoothly reach the photoelectric conversion area 170. In some example embodiments, when the upper insulating film 310 is used as the fixed charge layer, the upper insulating layer 310 may have negative fixed charges. For example, the upper insulating film 310 may include a metal oxide or a metal fluoride containing at least one of hafnium, zirconium, tantalum, yttrium, or lanthanide. In some example embodiments, the upper insulating film 310 may include the fixed charge layer and the antireflective layer that are sequentially stacked. In some example embodiments, the upper insulating film 310 may include or further include at least one of a silicon oxide, a silicon nitride, and a silicon oxynitride.

The grid pattern 330 may be provided on the second surface 110b of the substrate 110 with the upper insulating film 310 interposed therebetween. The grid pattern 330 may define openings corresponding to the pixel regions PXR. A color filter array CFA including color filters CF arranged two-dimensionally may be provided on the second surface 110b of the substrate 110. The color filter array CFA may be provided on the upper insulating film 310, and each of the color filters CF may fill a corresponding one(s) of the openings of the grid pattern 330. A lens array MLA including microlenses ML arranged two-dimensionally may be provided on the second surface 110b of the substrate 110 with the color filter array CFA interposed therebetween. For example, the color filter array CFA may be disposed between the lens array MLA and the upper insulating film 310.

In some example embodiments, each of the color filters CF may cover corresponding ones of the pixel regions PXR. For example, each of the color filters CF may be disposed on four pixel regions PXR arranged in a 2×2 matrix from a plan view (e.g., when viewed from a plan view). For example, each of the color filters CF may cover a pair of pixel region groups PXG adjacent to each other. However, example embodiments of the present inventive concepts are not limited thereto.

Each of the color filters CF may vertically overlap corresponding ones of the pixel region groups PXG. Each of the color filters CF may cover the pixel regions PXR included in the corresponding pixel region groups PXG. However, example embodiments of the present inventive concepts are not limited thereto. In some example embodiments, each of the color filters CF may have a structure that is laterally offset from the corresponding pixel region groups PXG. The offset structure may be intentionally selected to optimize a light path in consideration of a margin of a manufacturing process and/or a traveling angle of incident light. In some example embodiments, the offset structure may be selected based on an advantageous or alternatively desired optimization of a light path in consideration of a margin of a manufacturing process and/or a traveling angle of incident light.

Each of the color filters CF may have one color of red, green, and blue. Alternatively, in some example embodiments, each of the color filters CF may have one color of cyan, magenta, and yellow.

The grid pattern 330 may guide incident light into the photoelectric conversion area 170. The grid pattern 330 may have a single-layer structure or a multi-layer structure. The grid pattern 330 may include a metal-containing material (e.g., a metal (such as titanium) and/or a metal nitride (such as a titanium nitride)) and/or a low refractive material. The low refractive material may include a polymer and silica nanoparticles in the polymer. The low refractive material may have an insulating property.

In some example embodiments, the grid pattern 330 may vertically overlap the first and second deep trench isolations 130 and 150. However, example embodiments of the present inventive concepts are not limited thereto. In some example embodiments, the grid pattern 330 may have a structure that is laterally offset from the first and second deep trench isolation layers 130 and 150. The offset structure may be intentionally or advantageously selected to optimize a light path in consideration of a margin of a manufacturing process and/or a traveling angle of incident light.

The microlenses ML may each cover the pixel region groups PXG. For example, each of the microlenses ML may vertically overlap a corresponding one of the pixel region groups PXG. Therefore, in some example embodiments, each of the microlenses ML may cover a pair of pixel regions PXR included in the corresponding pixel region group PXG. Each of the microlenses ML may vertically overlap a pair of photoelectric conversion areas 170 formed in the pair of pixel regions PXR. In some example embodiments, each of the microlenses ML of the lens array MLA may vertically overlap a corresponding one of the pixel region groups PXG. Each of the microlenses ML may be provided to concentrate the incident light and may include a spherical lens, an aspherical lens, or a combination thereof. For example, each of the microlenses ML may have a shape that is convex upward from a cross-sectional view (e.g., when viewed from a cross-sectional view).

Each of the microlenses ML of the lens array MLA may have a shape with a long axis AX1 and a short axis AX2 from a plan view. For example, each of the microlenses ML of the lens array MLA may have a shape that may include a long axis AX1 and a short axis AX2 when viewed from a plan view. The short axis AX2 may be perpendicular or substantially perpendicular to the long axis AX1 and may be shorter than the long axis AX1. For example, each of the microlenses ML may have an elliptical shape or a bar shape from a plan view (e.g., when viewed from a plan view).

As described above, according to some example embodiments, a pair of pixels may be respectively formed in and on a pair of pixel regions PXR of the pixel region group PXG covered by each of the microlenses ML. The pair of pixels may be covered by the same color filter CF. In some example embodiments, the pair of pixels may perform an autofocus function in addition to a photoelectric conversion function that converts optical signals into electrical signals. For example, the pair of pixels may detect a phase difference of light incident through the corresponding microlens ML, and the autofocus function may be performed using the detected phase difference data. For example, the detected phase difference data may be transmitted or sent to the above-described autofocus circuit (not shown), and the autofocus circuit may adjust an objective lens (not shown) using the transmitted or sent phase difference data.

As described above, according to some example embodiments, the microlenses ML may respectively cover the pixel region groups PXG, and the pair of pixels formed in each of the pixel region groups PXG may perform the autofocus function. Accordingly, the autofocus function may be performed anywhere in the pixel array. For example, the autofocus function may be performed at any desired location in the pixel array. As a result, the degree of freedom and/or efficiency of the autofocus function of the image sensor can be improved.

In FIGS. 3, 4A, and 4B, each of the microlenses ML may be vertically aligned with the corresponding pixel region group PXG. However, example embodiments of the present inventive concepts are not limited thereto. In some example embodiments, at least one of the microlenses ML may be laterally shifted from the corresponding pixel region group PXG. For example, even when at least one of the microlenses ML may be laterally shifted from the corresponding pixel region group PXG, the shifted microlens ML may cover at least a portion of each of the pair of pixel regions PXR of the corresponding pixel region group PXG. For example, in order to optimize the margin of the manufacturing process and/or the optical path, when the grid pattern 330 has the offset structure, at least one of the microlenses ML may have the shifted structure. For example, the microlenses ML located in a central portion of the pixel array may be vertically aligned with the corresponding pixel region groups PXG, and the microlenses ML located in an edge portion of the pixel array may have the shifted structure.

The microlenses ML are transparent to transmit or sent light. The microlenses ML may be formed of an organic material such as polymer. For example, the microlenses ML may include a photoresist material or a thermosetting resin.

According to some example embodiments, when light is incident on the second surface 110b of the substrate 110, the light may be incident on the first and second deep trench isolation layers 130 and 150. For example, the first and second buried conductive patterns 135 and 155 may absorb the light. For example, when the first and second buried conductive patterns 135 and 155 include doped polysilicon, the first and second buried conductive patterns 135 and 155 may absorb the light. Thus, the amount of light incident on the photoelectric conversion areas 170 may decrease, thereby causing light loss.

However, according to some example embodiments, one portion P1 (e.g., the first portion P1) of the second deep trench isolation layer 150 having the relatively small width WD2 may not include the second buried conductive pattern 155. Therefore, light loss at one portion P1 (e.g., the first portion P1) of the second deep trench isolation layer 150 can be reduced, minimized, or prevented. For example, the second deep trench isolation layer 150 may overlap or be adjacent to the focus line of the microlens ML. In other words, because one portion P1 (e.g., the first portion P1) of the second deep trench isolation layer 150 does not include the second buried conductive pattern 155, light loss at the focus line of the microlens ML can be reduced, minimized, or prevented. As a result, according to some example embodiments, the photoelectric conversion efficiency of the pair of pixels can be improved, thereby allowing the photoelectric conversion function and/or the autofocus function to be smoothly performed.

Referring to FIG. 3, the long axes AX1 of the microlenses ML may be parallel to each other. For example, the long axes AX1 of all the microlenses ML included in the lens array MLA may be parallel to a first direction D1.

The pair of pixel regions PXR of each of the pixel region groups PXG may be arranged in a direction parallel to the long axis AX1 of the microlens ML corresponding to each of the pixel region groups PXG (e.g., the first direction D1).

Each of the pixel regions PXR may have a first width W1 in the direction parallel to the long axis AX1 of the microlens ML (e.g., the first direction D1) and a second width W2 in a direction parallel to the short axis AX2 of the microlens ML (e.g., a second direction D2). The second width W2 may be smaller than twice the first width W1. In some example embodiments, the first width W1 may be about 80% to about 120% of the second width W2. For example, the first width W1 may be the same or substantially the same as the second width W2. Since each of the pair of pixel regions PXR has the first and second widths W1 and W2 of the condition (e.g., the first width W1 being the same or substantially the same as the second width W2), most of the pair of pixel regions PXR may be covered by the microlens ML having the long axis AX1 and the short axis AX2.

In some example embodiments, e.g., as illustrated in FIG. 3, a length of one portion P1 (e.g., the first portion P1) of the second deep trench isolation layer 150 in the second direction D2 may be about 10% or more of a total length of the second deep trench isolation layer 150 in the second direction D2. Thus, in some example embodiments, light loss can be sufficiently reduced. In some example embodiments, the width WD2 of one portion P1 (e.g., the first portion P1) of the second deep trench isolation layer 150 may be about 40% to about 80% of the width WD1 of the first deep trench isolation layer 130. Thus, in some example embodiments, one portion P1 (e.g., the first portion P1) of the second deep trench isolation layer 150 may not include the second buried conductive pattern 155 or may include the second buried conductive pattern 155 having a width smaller than the width of the first buried conductive pattern 135.

As described above, in some example embodiments, when the length of one portion P1 (e.g., the first portion P1) of the second deep trench isolation layer 150 is about 10% or more of the total length of the second deep trench isolation layer 150 and the width WD2 of one portion P1 (e.g., the first portion P1) of the second deep trench isolation layer 150 is about 40% to about 80% of the width WD1 of the first deep trench isolation layer 130, the sensitivity to blue light can be increased by about 6% to about 7%, and the sensitivity to red light can be increased by about 1% to about 3%.

As described above, in some example embodiments, the width WD3 of the other portion P2 (e.g., the second portion P2) of the second deep trench isolation layer 150 may be the same or substantially the same as the width WD1 of the first deep trench isolation layer 130. For example, as shown in FIG. 4B, the width WD3a of the second buried conductive pattern 155 of the other portion P2 (e.g., the second portion P2) of the second deep trench isolation layer 150 may be the same or substantially the same as the width WD1a of the first buried conductive pattern 135 of the first deep trench isolation layer 130. Alternatively, in some example embodiments, when the width WD3 of the other portion P2 (e.g., the second portion P2) of the second deep trench isolation layer 150 is smaller than the width WD1 of the first deep trench isolation layer 150, the width WD3a of the second buried conductive pattern 155 of the other portion P2 (e.g., the second portion P2) of the second deep trench isolation layer 150 may be smaller than the width WD1a of the first buried conductive pattern 135 of the first deep trench isolation layer 130.

As described above, in some example embodiments, the first and second deep trench isolation layers 130 and 150 may pass through the substrate 110 and the shallow trench isolation layer 160. However, example embodiments of the present inventive concepts are not limited thereto. According to some example embodiments, the first and second deep trench isolation layers 130 and 150 may pass through the substrate 110 but may not pass through the shallow trench isolation layer 160. For example, the first and second capping insulating patterns 138 and 158 may be omitted. In some example embodiments, the lower ends of the first and second deep trench isolation layers 130 and 150 may be in contact with the shallow trench isolation layer 160. For example, the first insulating liner 133 may extend and be disposed between the first buried conductive pattern 135 and the shallow trench isolation layer 160, and the second insulating liner 153 may extend and be disposed between the second buried conductive pattern 155 and the shallow trench isolation layer 160. Alternatively, in some example embodiments, the lower ends of the first and second deep trench isolation layers 130 and 150 may be spaced apart from the shallow trench isolation layer 160. For example, the first insulating liner 133 may extend and be disposed between the lower end of the first buried conductive pattern 135 and the substrate 110, and the second insulating liner 153 may extend and be disposed between the lower end of the second buried conductive pattern 155 and the substrate 110.

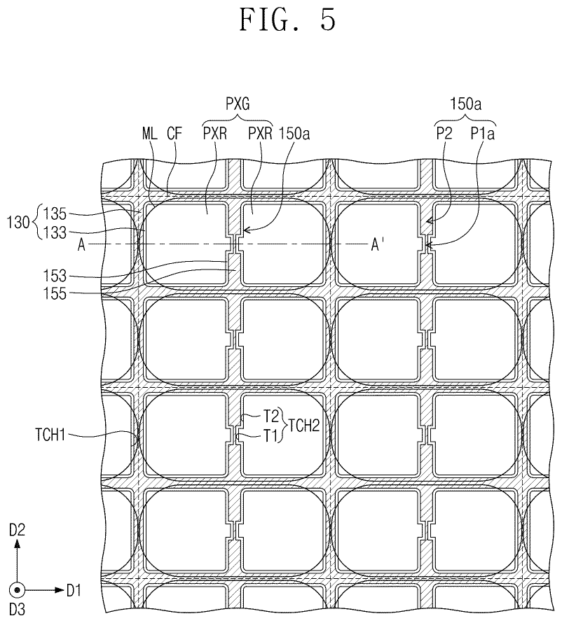

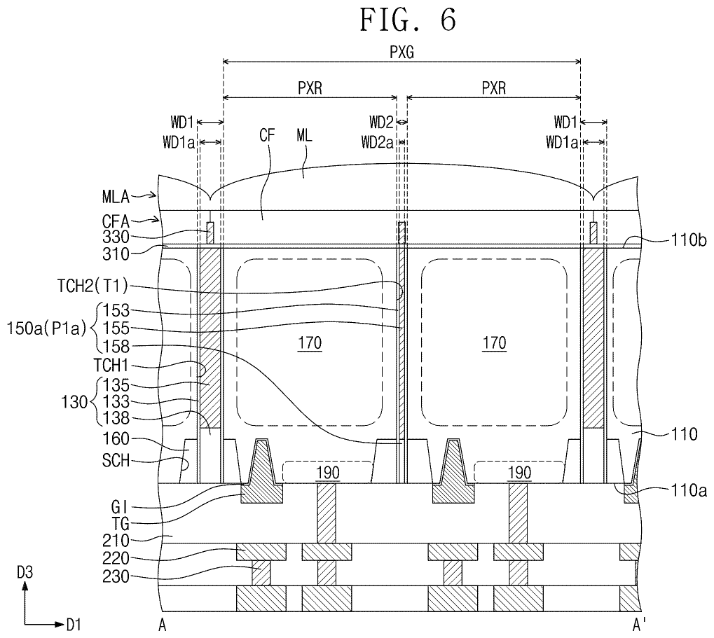

FIG. 5 is a plan view showing an image sensor according to some example embodiments, and FIG. 6 is a cross-sectional view taken along line A-A′ of FIG. 5 according to some example embodiments. Hereinafter, for convenience of explanation, differences between the above-described example embodiments and the present example embodiments will mainly be described.

Referring to FIGS. 5 and 6, one portion Pla (e.g., a first portion Pla) of a second deep trench isolation layer 150a may fill one area T1 (e.g., a first area T1) of a second deep trench TCH2, and the other portion P2 (e.g., the second portion P2) of the second deep trench isolation layer 150a may fill the other area T2 (e.g., the second area T2) of the second deep trench TCH2. A width WD2 of the one portion Pla (e.g., the first portion Pla) of the second deep trench isolation layer 150a may be smaller than a width WD1 of a first deep trench isolation layer 130.

The second deep trench isolation layer 150a may include a second buried conductive pattern 155, a second capping insulating pattern 158, and a second insulating liner 153. According to some example embodiments, one portion Pla (e.g., the first portion Pla) of the second deep trench isolation layer 150a may also include the second buried conductive pattern 155. According to some example embodiments, since the width WD2 of the one portion Pla (e.g., the first portion Pla) of the second deep trench isolation layer 150a is smaller than the width WD1 of the first deep trench isolation layer 130, a width WD2a of the second buried conductive pattern 155 of the one portion Pla (e.g., the first portion Pla) of the second deep trench isolation layer 150a may be smaller than a width WD1a of the first buried conductive pattern 135 of the first deep trench isolation layer 130. Therefore, in some example embodiments, even though the one portion Pla (e.g., the first portion Pla) of the second deep trench isolation layer 150a having the relatively small width WD2 includes the second buried conductive pattern 155, light loss due to the second deep trench isolation layer 150a can be reduced. In some example embodiments, the second buried conductive pattern 155 of one portion Pla of the second deep trench isolation layer 150a may include a void such as an air gap therein.

Other features of the image sensor of FIGS. 5 and 6, according to some example embodiments, may be the same as/similar to the corresponding features of the image sensor of FIGS. 3, 4A, and 4B.

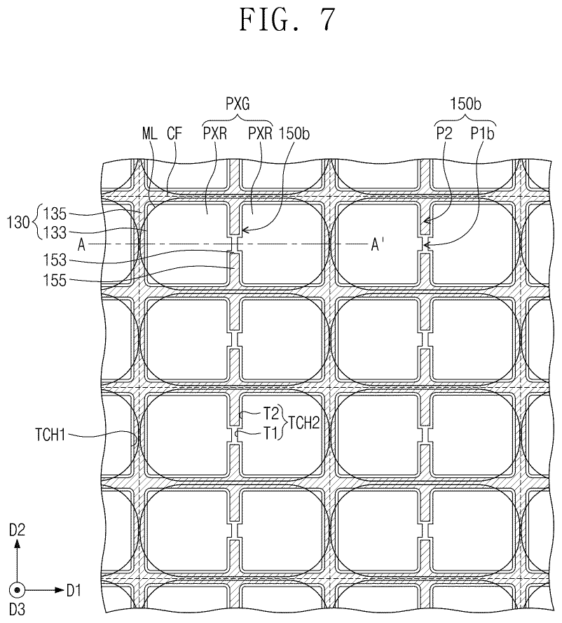

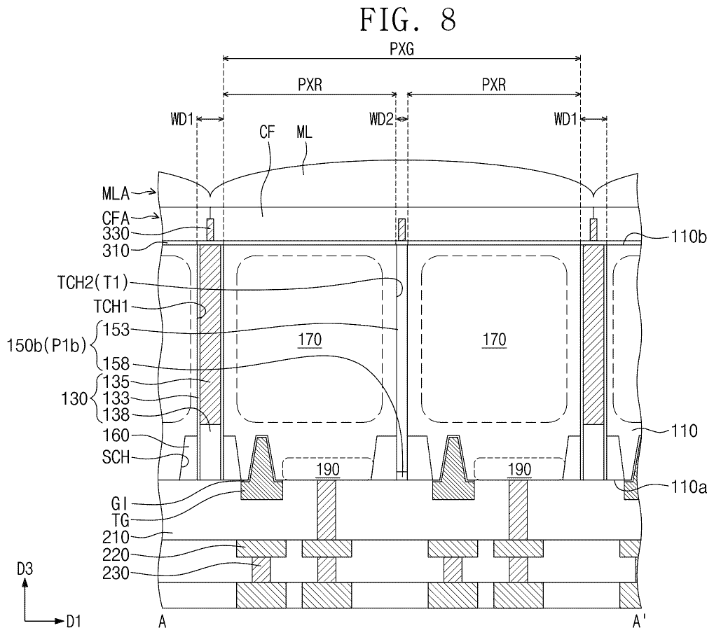

FIG. 7 is a plan view showing an image sensor according to some example embodiments, and FIG. 8 is a cross-sectional view taken along line A-A′ of FIG. 7 according to some example embodiments. Hereinafter, for convenience of explanation, differences between the above-described example embodiments and the present example embodiments will mainly be described.

Referring to FIGS. 7 and 8, one portion P1b (e.g., a first portion P1b) of a second deep trench isolation layer 150b filling one area T1 (e.g., a first area T1) of a second deep trench TCH2 may include a second insulating liner 153 and a second capping insulating pattern 158. A width WD2 of the one portion P1b (e.g., the first portion P1b) of the second deep trench isolation layer 150b may be smaller than a width WD1 of a first deep trench isolation layer 130.

According to some example embodiments, the one portion P1b (e.g., the first portion P1b) of the second deep trench isolation layer 150b may not have the void VD illustrated in, for example, FIG. 4A. In other words, the one area T1 (e.g., the first area T1) of the second deep trench TCH2 may be filled by the second insulating liner 153 and the second capping insulating pattern 158. In some example embodiments, a height of the second capping insulating pattern 158 of the one portion P1b (e.g., the first portion P1b) of the second deep trench isolation layer 150b may be smaller than a height of the second capping insulating pattern 158 of the other portion P2 (e.g., the second portion P2) of the second deep trench isolation layer 150b. However, example embodiments of the present inventive concepts are not limited thereto. In some example embodiments, the second capping insulating pattern 158 of the one portion P1b (e.g., the first portion P1b) of the second deep trench isolation layer 150b may be omitted. For example, the one area T1 (e.g., the first area T1) of the second deep trench TCH2 may be filled with the second insulating liner 153.

Other features of the image sensor of FIGS. 7 and 8 according to some example embodiments may be the same as/similar to the corresponding features of the image sensor of FIGS. 3, 4A, and 4B.

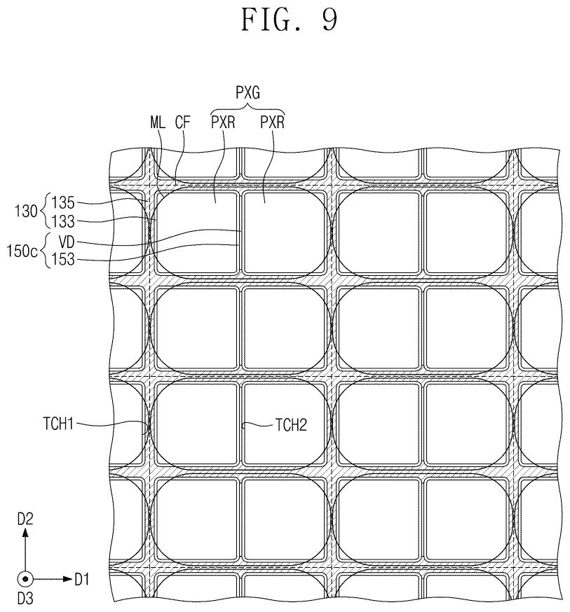

FIG. 9 is a plan view showing an image sensor according to some example embodiments. Hereinafter, for convenience of explanation, differences between the above-described example embodiments and the present example embodiments will mainly be described.

Referring to FIG. 9, the second deep trench isolation layer 150c may have a uniform or substantially uniform width from a plan view (e.g., when viewed in a plan view). Therefore, the second deep trench TCH2 in which the second deep trench isolation layer 150c is formed may also have a uniform or substantially uniform width from a plan view (e.g., when viewed in a plan view). The width of the second deep trench isolation layer 150c may be smaller than a width of the first deep trench isolation layer 130. In other words, the entire second deep trench isolation layer 150c may be narrower than the first deep trench isolation layer 130. For example, the width of the second deep trench isolation layer 150c may be about 40% to about 80% of the width of the first deep trench isolation layer 130.

The second deep trench isolation layer 150c may include a second insulating liner 153. In some example embodiments, as shown in FIG. 9, the second deep trench isolation layer 150c may further include a void VD. However, example embodiments of the present inventive concepts are not limited thereto. In some example embodiments, the second insulating liner 153 may fill the second deep trench, and the second deep trench isolation layer 150c may not include the void VD. In some example embodiments, the second deep trench isolation layer 150c may further include a second buried conductive pattern, and the second buried conductive pattern may have a uniform or substantially uniform width from a plan view (e.g., when viewed in a plan view), and the width of the second buried conductive pattern may be smaller than a width of the first buried conductive pattern 135.

Other features of the image sensor of FIG. 9 according to some example embodiments may be the same as or similar to corresponding features of the image sensor of FIGS. 3, 4A, and 4B.

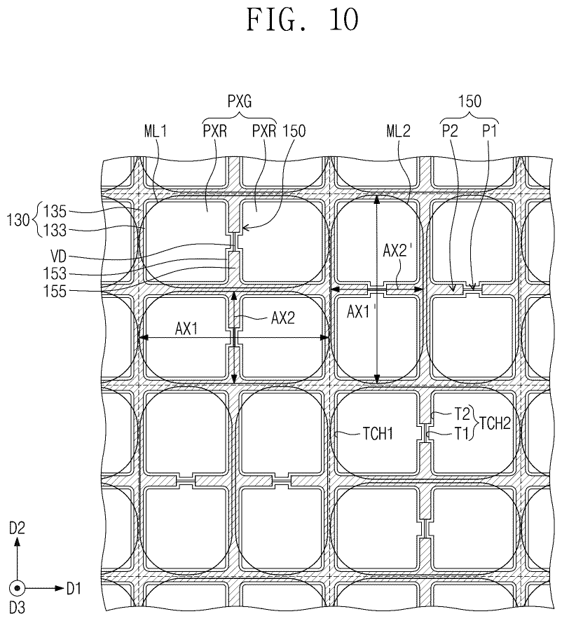

FIG. 10 is a plan view showing an image sensor according to some example embodiments. Hereinafter, for convenience of explanation, differences between the above-described example embodiments and the present example embodiments will mainly be described.

Referring to FIG. 10, from a plan view, a long axis AX1 of at least one ML1 of microlenses may be perpendicular or substantially perpendicular to a long axis AX1′ of at least the other one ML2 of microlenses. A length of the long axis AX1 of at least one of the microlens ML1 may be the same or substantially the same as a length of the long axis AX1′ of at least the other one of the microlens ML2. Likewise, a length of a short axis AX2 of at least one of the microlens ML1 may be the same or substantially the same as a length of a short axis AX2′ of at least the other one of the microlens ML2. For example, a long axis AX1 of at least a first microlens ML1 of microlenses ML may be perpendicular or substantially perpendicular to a long axis AX1′ of at least a second microlens ML2 of the microlenses ML. A length of the long axis AX1 of the first microlens ML1 may be the same or substantially the same as a length of the long axis AX1′ of the second microlens ML2. Likewise, a length of a short axis AX2 of the first microlens ML1 may be the same or substantially the same as a length of a short axis AX2′ of the second microlens ML2.

A color of a color filter CF under the at least one of the microlens ML1 (e.g., the first microlens ML1) may be different from a color of a color filter CF under the at least the other one of the microlens ML2 (e.g., the second microlens ML2).

In some example embodiments, the long axis AX1 of the at least one of the microlens ML1 (e.g., the first microlens ML1) may be parallel to a first direction D1, and the long axis AX1′ of at least the other one of the microlens ML2 (e.g., the second microlens ML2) may be parallel to a second direction D2. A pair of pixel regions PXR under the at least one of the microlens ML1 (e.g., the first microlens ML1) may be arranged in the first direction D1, and a pair of pixel regions PXR under at least the other one of the microlens ML2 (e.g., the second microlens ML2) may be arranged in the second direction D2. Accordingly, the second deep trench isolation layer 150 under at least one of the microlens ML1 (e.g., the first microlens ML1) may extend in the second direction D2, and the second deep trench isolation layer 150 under at least the other one of the microlens ML2 (e.g., the second microlens ML2) may extend in the first direction D1.

A pair of pixels under at least one of the microlens ML1 (e.g., the first microlens ML1) may perform a horizontal autofocus function from a plan view, and a pair of pixels under at least the other one of the microlens ML2 (e.g., the second microlens ML2) may perform a vertical autofocus function from a plan view.

In the image sensor according to some example embodiments, a lens array MLA may be composed of the microlenses ML1 and the microlenses ML2.

Other features of the image sensor of FIG. 10 according to some example embodiments may be the same as or similar to corresponding features of the image sensor of FIGS. 3, 4A, and 4B.

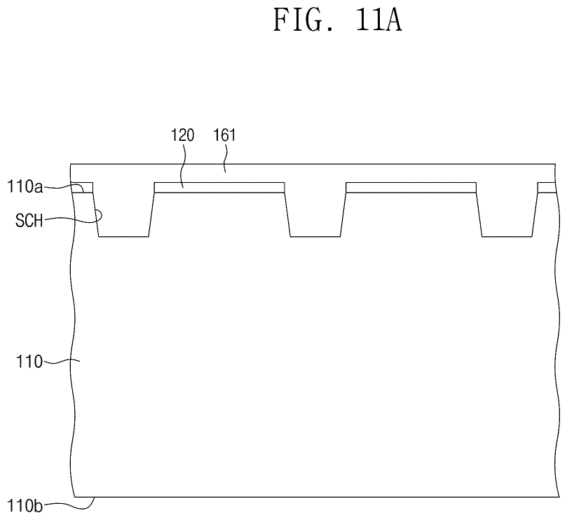

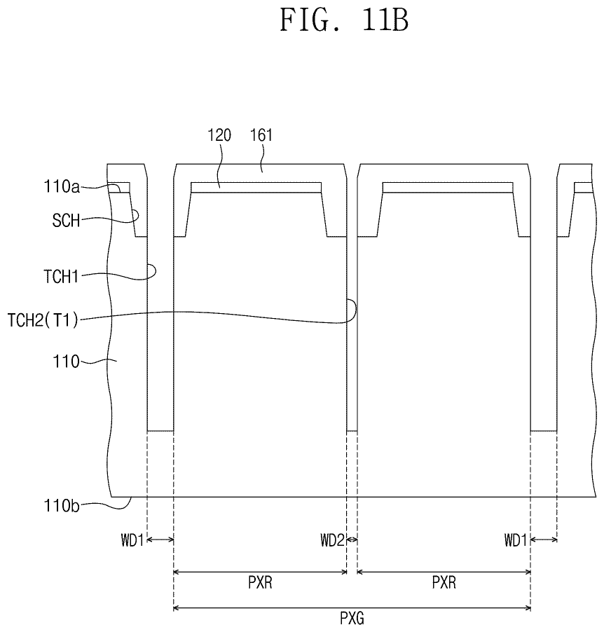

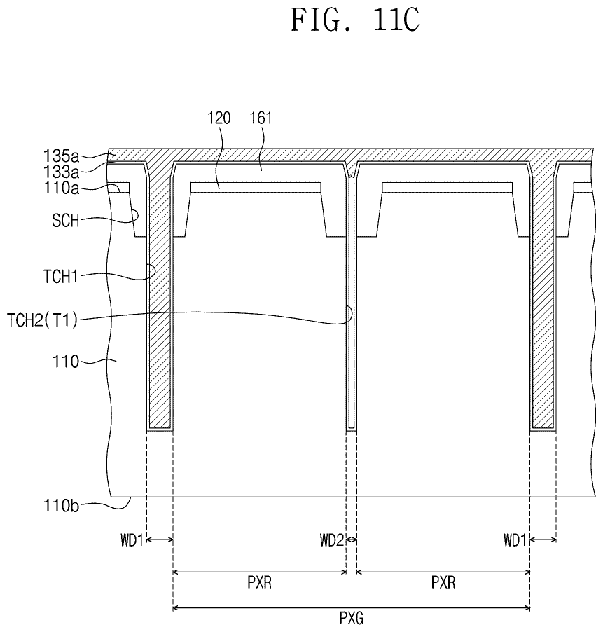

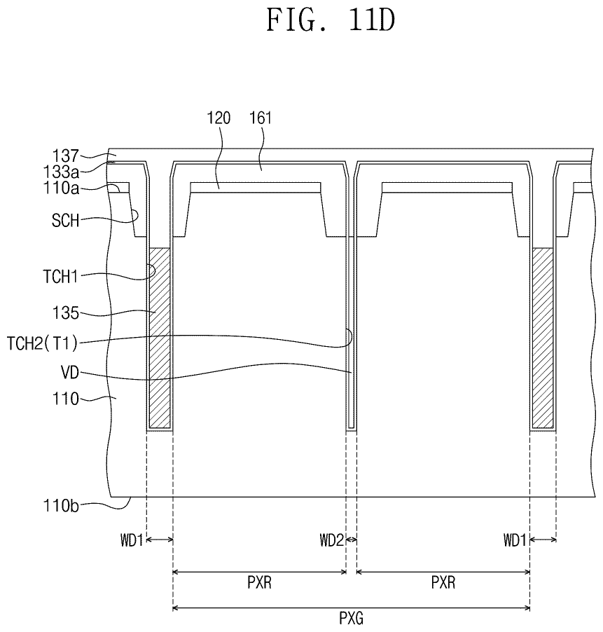

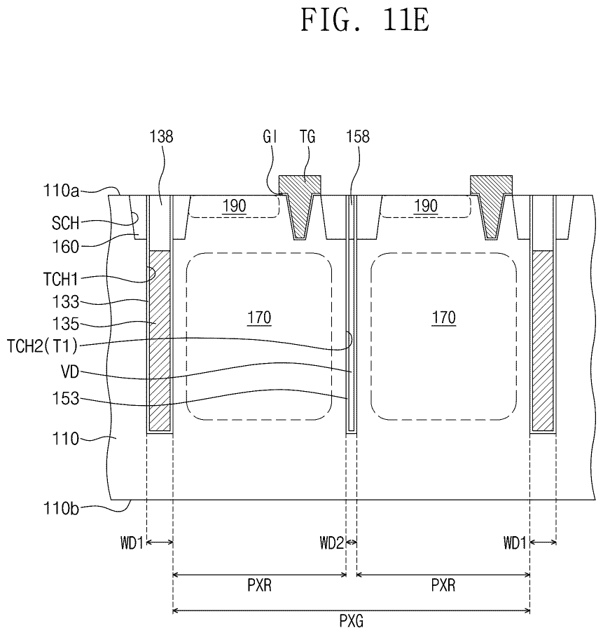

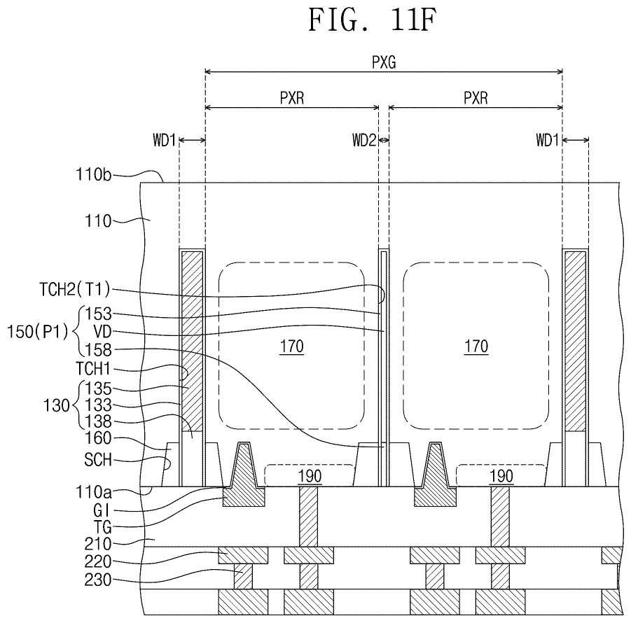

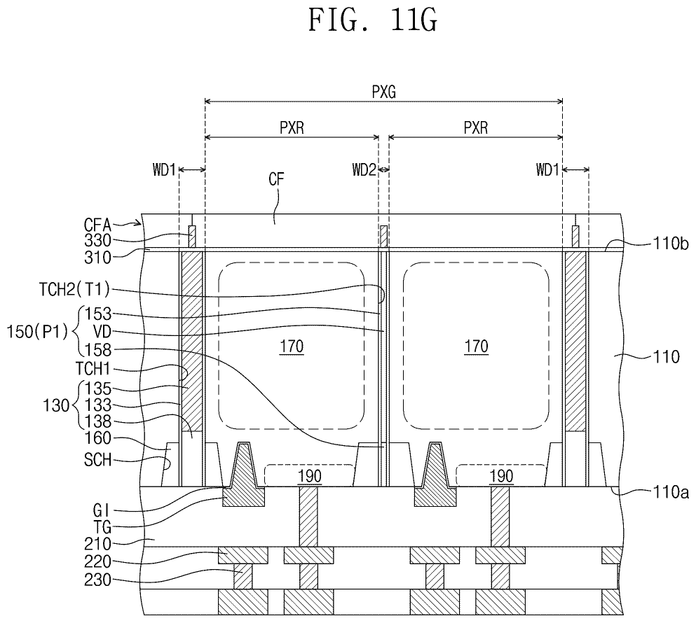

FIGS. 11A to 11G are cross-sectional views corresponding to line A-A′ of FIG. 3 to show a manufacturing method of an image sensor according to some example embodiments.

Referring to FIG. 11A, a hard mask pattern 120 defining a shallow trench SCH may be formed on a first surface 110a of a substrate 110. The hard mask pattern 120 may be formed of a material having etching selectivity with respect to the substrate 110. For example, the hard mask pattern 120 may be formed of at least one of a silicon oxide, a silicon nitride, or a silicon oxynitride. The substrate 110 may be doped with impurities of a first conductivity type.

The substrate 110 may be etched using the hard mask pattern 120 as an etching mask to form the shallow trench SCH. Subsequently, a first insulating layer 161 may be formed on the first surface 110a of the substrate 110 to fill the shallow trench SCH. The first insulating layer 161 may cover the hard mask pattern 120. The first insulating layer 161 may include an insulating material. The first insulating film 161 may be formed using at least one of a deposition process or an oxidation process.

Referring to FIG. 11B, the first insulating layer 161 and the substrate 110 may be patterned to form first and second deep trenches TCH1 and TCH2. The first and second deep trenches TCH1 and TCH2 may extend from the first surface 110a of the substrate 110 toward a second surface 110b of the substrate 110. Bottom surfaces of the first and second deep trenches TCH1 and TCH2 may be spaced apart from the second surface 110b of the substrate 110. The first and second deep trenches TCH1 and TCH2 may pass through portions of the first insulating layer 161 in the shallow trench SCH. The first deep trench TCH1 may define pixel region groups PXG, and the second deep trench TCH2 may be formed between a pair of pixel regions PXR of each of the pixel region groups PXG. For example, the first and second deep trenches TCH1 and TCH2 may define pixel regions PXR. In some example embodiments, a width WD2 of at least one portion (e.g., a first portion) of the second deep trench TCH2 may be smaller than a width WD1 of the first deep trench TCH1.

Referring to FIG. 11C, an insulating liner layer 133a may be conformally formed on the first surface 110a of the substrate 110 having the first and second deep trenches TCH1 and TCH2, and a buried conductive layer 135a may be formed on the insulating liner layer 133a to fill the first deep trench TCH1. The insulating liner layer 133a may be formed using at least one of a deposition process or an oxidation process, and the buried conductive layer 135a may be formed using a deposition process.

Accordingly, in some example embodiments, since the at least one portion (e.g., the first portion) of the second deep trench TCH2 has a relatively small width WD2, the buried conductive layer 135a may not fill the at least one portion (e.g., the first portion) of the second deep trench TCH2. However, example embodiments of the present inventive concepts are not limited thereto. In some example embodiments, the buried conductive layer 135a may fill the at least one portion (e.g., the first portion) of the second deep trench TCH2.

Referring to FIG. 11D, the buried conductive layer 135a may be etched to form the first buried conductive pattern 135 in the first deep trench TCH1. For example, as shown in FIG. 4B, the second buried conductive pattern 155 may be formed in the other area T2 (e.g., the second area T2) of the second deep trench TCH2. Upper ends of the first and second buried conductive patterns 135 and 155 may be lower than the first surface 110a of the substrate 110.

Subsequently, a second insulating layer 137 may be formed on the substrate 110 having the first and second buried conductive patterns 135 and 155. The second insulating layer 137 may cover the insulating liner layer 133a, the first insulating layer 161, and the first and second buried conductive patterns 135 and 155. The second insulating layer 137 may fill upper areas of the first and second deep trenches TCH1 and TCH2. The second insulating layer 137 may include an insulating material. The second insulating layer 137 may be formed by a deposition process.

The second insulating layer 137 may fill an upper area of one area T1 (e.g., a first area T1) of the second deep trench TCH2 to define a void VD in the one area T1 (e.g., the first area T1) of the second deep trench TCH2.

Referring to FIG. 11E, a planarization process may be performed on the second insulating layer 137 until the first surface 110a of the substrate 110 is exposed. The hard mask pattern 120, the first insulating layer 161, the insulating liner layer 133a, and the second insulating layer 137 on the first surface 110a may be removed by the planarization process. The planarization process may be performed using at least one of an etch-back process or a chemical mechanical polishing (CMP) process.

The first insulating liner 133, the second insulating liner 153, the first capping insulating pattern 138, the second capping insulating pattern 158, and the shallow trench isolation layer 160 may be formed by the planarization process and may be exposed on the first surface 110a of the substrate 110.

The shallow trench isolation layer 160 may be provided in the shallow trench SCH to define active areas in the pixel regions PXR. Each of the active areas may be a portion of the substrate 110 surrounded by the shallow trench isolation layer 160 from a plan view.

The first capping insulating pattern 138, the first insulating liner 133, and the first buried conductive pattern 135 may configure the first deep trench isolation layer 130. The second capping insulating pattern 158, the second insulating liner 153, the second buried conductive pattern 155 (see, e.g., FIG. 4B), and the void VD may configure the second deep trench isolation layer 150.

Impurities of a second conductivity type may be implanted into the substrate 110 to form photoelectric conversion areas 170 in each of the pixel regions PXR. In some example embodiments, the photoelectric conversion areas 170 may be formed before forming the shallow trench SCH or after forming the first and second deep trench isolation layers 130 and 150.

A gate trench may be formed in the corresponding active areas of each of the pixel regions PXR. A gate dielectric layer GI may be formed on inner surfaces of the gate trenches and on the active areas, and a gate conductive layer may be formed on the gate dielectric layer GI. The gate conductive layer may fill the gate trenches. The gate conductive layer may be patterned to form transfer gates TG. For example, gates of logic transistors may also be formed on the corresponding active areas of each of the pixel regions PXR. Impurities of a second conductivity type may be implanted into the active areas to form floating diffusion regions 190. For example, source/drain areas of the logic transistors may also be formed in the corresponding active areas.

Referring to FIG. 11F, interlayer insulating layers 210, wirings 220, and contact plugs 230 may be formed on the first surface 110a of the substrate 110. To implement the pixel PXL of, e.g., FIG. 2, the wirings 220 and the contact plugs 230 may be properly connected to the gates, the floating diffusion region 190, and the source/drain areas. Subsequently, the substrate 110 may be turned over.

Referring to FIG. 11G, the second surface 110b of the substrate 110 may be polished until the first and second buried conductive patterns 135 and 155 are exposed. The second surface 110b of the substrate 110 may be polished through a chemical mechanical polishing (CMP) process. A hydrogen/deuterium annealing process may be performed to heal defects (e.g., dangling bonds, etc.) of the polished second surface 110b of the substrate 110.

An upper insulating film 310 may be conformally formed on the second surface 110b of the substrate 110. A grid pattern 330 may be formed on the upper insulating layer 310, and a color filter array CFA including color filters CF may be formed on the second surface 110b of the substrate 110 having the grid pattern 330.

Referring back to FIGS. 4A and 4B, a lens array MLA including microlenses ML may be formed on the color filter array CFA.

In some example embodiments, in the structure of FIG. 11C, the buried conductive layer 135a may also be formed in the one area T1 (e.g., the first area T1) of the second deep trench TCH2. For example, the image sensor of FIG. 6 according to some example embodiments may be manufactured.

Hereinafter, a manufacturing method of the image sensor of FIG. 8 will be described according to some example embodiments. In some example embodiments, in the structure of FIG. 11C, the insulating liner layer 133a may fill the one area T1 (e.g., the first area T1) of the second deep trench TCH2 without a void. For example, the image sensor of FIG. 8 may be manufactured.

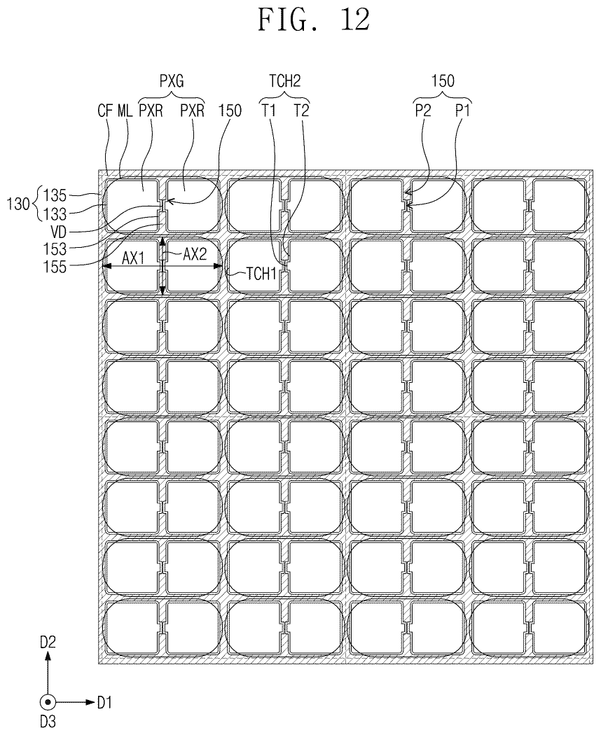

FIG. 12 is a plan view showing an image sensor according to some example embodiments. Hereinafter, for convenience of explanation, differences between the above-described example embodiments and the present example embodiments will mainly be described.

Referring to FIG. 12, each of the color filters CF of the color filter array CFA may cover eight pixel region groups PXG adjacent to each other, and the pixel regions PXR of the eight pixel region groups PXG may be arranged in a 4×4 matrix form.

Other features of the image sensor of FIG. 12 according to some example embodiments may be the same as or similar to corresponding features of the image sensor of FIGS. 3, 4A, and 4B.

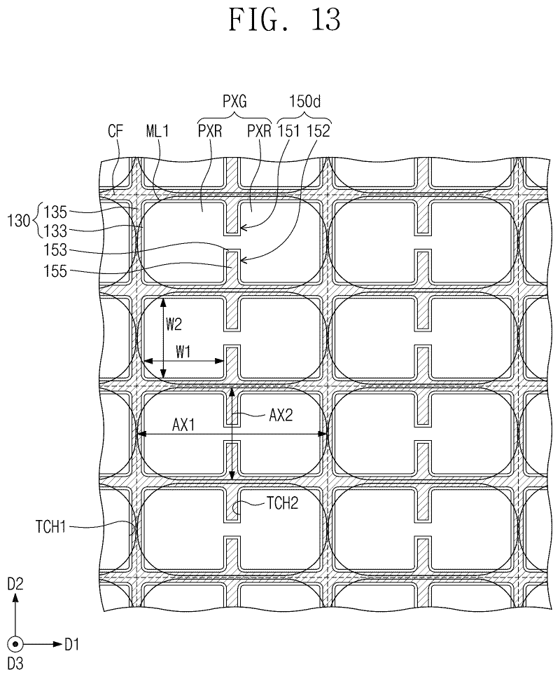

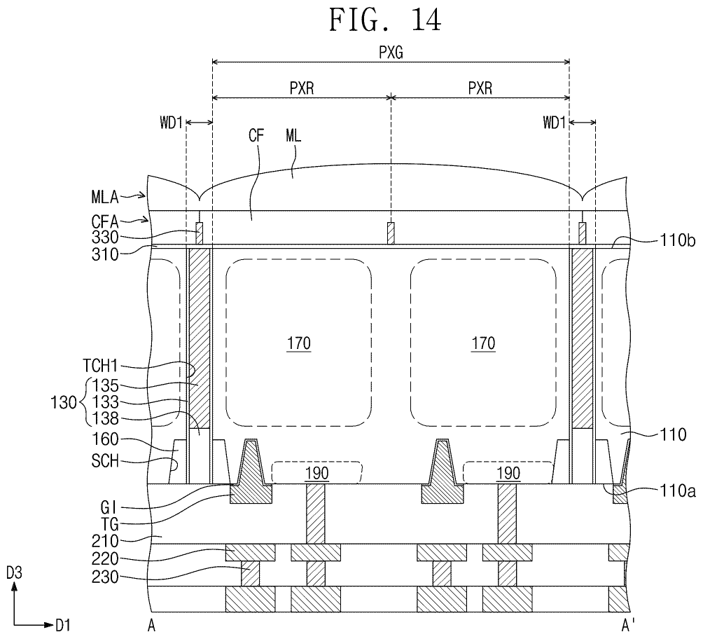

FIG. 13 is a plan view showing an image sensor according to some example embodiments, and FIG. 14 is a cross-sectional view taken along line A-A′ of FIG. 13 according to some example embodiments. Hereinafter, for convenience of explanation, differences between the above-described example embodiments and the present example embodiments will mainly be described.

Referring to FIGS. 13 and 14, a second deep trench isolation layer 150d according to some example embodiments may have a first portion 151 and a second portion 152 that are spaced apart from each other in a direction (e.g., the second direction D2) parallel to a short axis AX2 of a microlens ML. A pair of pixel regions PXR of each of the pixel region groups PXG may be connected to each other without an interface between the first portion 151 and the second portion 152 of the second deep trench isolation layer 150d.

In other words, a connected portion of the pair of pixel regions PXR may be provided between the first portion 151 and the second portion 152 of the second deep trench isolation layer 150d. Accordingly, in some example embodiments, a buried conductive pattern may not exist between the first portion 151 and the second portion 152 of the second deep trench isolation layer 150d. As a result, light loss at the connected portion of the pair of pixel regions PXR may be minimized, reduced, or prevented.

The first portion 151 and the second portion 152 of the second deep trench isolation layer 150d may be connected to the first deep trench isolation layer 130. Each of the first and the second portions 151 and 152 of the second deep trench isolation layer 150d may include a second buried conductive pattern 155 and a second insulating liner 153. According to some example embodiments, a width of each of the first and the second portions 151 and 152 of the second deep trench isolation layer 150d may be the same or substantially the same as a width of the first deep trench isolation layer 130 or be smaller than the width of the first deep trench isolation layer 130.

Other features of the image sensor of FIGS. 13 and 14 according to some example embodiments may be the same as/similar to the corresponding features of the image sensors of FIGS. 3, 4A, and 4B.

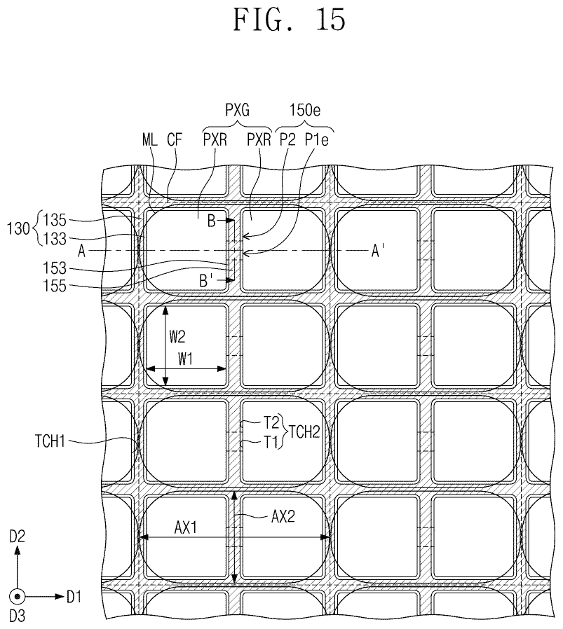

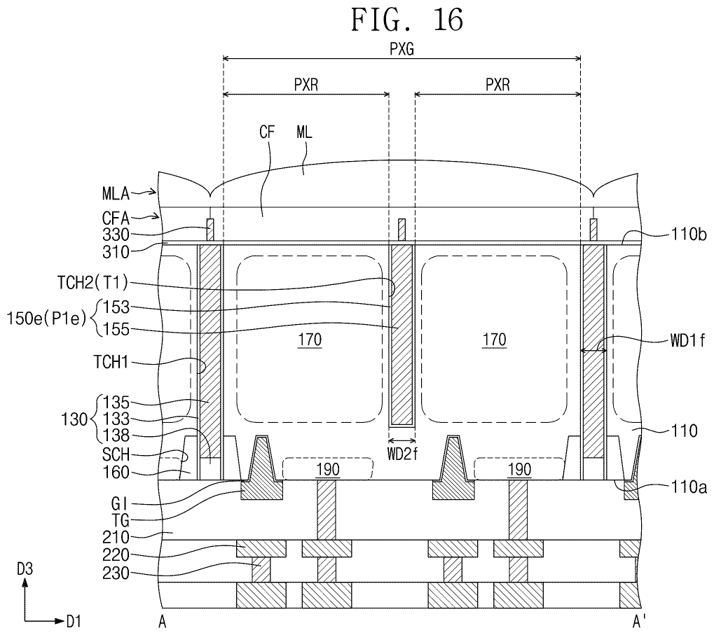

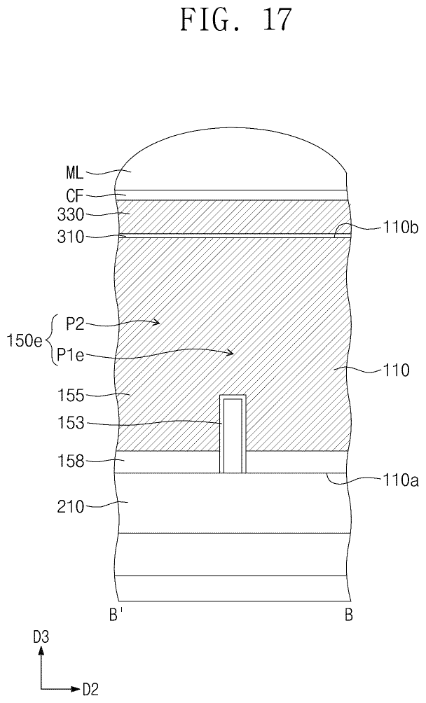

FIG. 15 is a plan view showing an image sensor according to some example embodiments, and FIGS. 16 and 17 are cross-sectional views taken along lines A-A′ and B-B′ of FIG. 15, respectively, according to some example embodiments. Hereinafter, for convenience of explanation, differences between the above-described example embodiments and the present example embodiments will mainly be described.

Referring to FIGS. 15 and 16, first and second deep trenches TCH1 and TCH2 may be formed in a substrate 110 between a pair of pixel regions PXR.

At least one portion P1e (e.g., a first portion P1e) of a second deep trench isolation layer 150e and a first deep trench isolation layer 130 may have different depths. In other words, a depth of one area T1 (e.g., a first area T1) of a second deep trench TCH2 and a depth of a first deep trench TCH1 may be formed differently. According to some example embodiments, the one area T1 (e.g., the first area T1) of the second deep trench TCH2 may be spaced apart from the first surface 110a of the substrate 110.

Referring to FIG. 17, the at least one portion P1e (e.g., the first portion P1e) of the second deep trench isolation layer 150e and the other portion P2 (e.g., the second portion P2 of the second deep trench isolation layer 150e may have different depths. In other words, depths of the one area T1 (e.g., the first area T1) and the other area T2 (e.g., the second area T2) of the second deep trench TCH2 may be formed differently.

A width WD2f of the one area T1 (e.g., the first area T1) of the second deep trench TCH2 may be the same or substantially the same as a width WD1f of the first deep trench TCH1. However, example embodiments of the present inventive concepts are not limited thereto, and in some example embodiments the width WD2f of the one area T1 (e.g., the first area T1) of the second deep trench TCH2 may be smaller than the width WD1f of the first deep trench TCH1.

The first and second deep trench isolation layers 150e may have the same or substantially the same width from a plan view (e.g., when viewed in a plan view). Therefore, in some example embodiments, the first deep trench TCH1 in which the first deep trench isolation layer 130 is formed and the second deep trench TCH2 in which the second deep trench isolation layer 150e is formed may also have the same or substantially the same width from a plan view (e.g., when viewed in a plan view). The width of the second deep trench isolation layer 150e may be smaller than a width of the first deep trench isolation layer 130. In other words, the entire second deep trench isolation layer 150e may be narrower than the first deep trench isolation layer 130. For example, the width of the second deep trench isolation layer 150e may be about 40% to about 80% of the width of the first deep trench isolation layer 130.

The at least one portion P1e (e.g., the first portion P1e) of the second deep trench isolation layer 150e may include a second insulating liner 153. In some example embodiments, the at least one portion P1e (e.g., the first portion P1e) of the second deep trench isolation layer 150e may further include a void VD. However, example embodiments of the present inventive concepts are not limited thereto. In some example embodiments, the second insulating liner 153 may fill the one area T1 (e.g., the first area T1) of the second deep trench TCH2, and the at least one portion P1e (e.g., the first portion P1e) of the second deep trench isolation layer 150e may not include a void VD. In some example embodiments, the at least one portion P1e (e.g., the first portion P1e) of the second deep trench isolation layer 150e may further include a second buried conductive pattern 155, and the second buried conductive pattern 155 may have a uniform or substantially uniform width with the first buried conductive pattern 135 of the first deep trench isolation layer 130 from a plan view (e.g., when viewed in plan view), and the width of the second buried conductive pattern 155 may be smaller than the width of the first buried conductive pattern 135.

Other features of the image sensor of FIGS. 15, 16 and 17 according to some example embodiments may be the same as/similar to the corresponding features of the image sensor of FIGS. 3, 4A, and 4B.

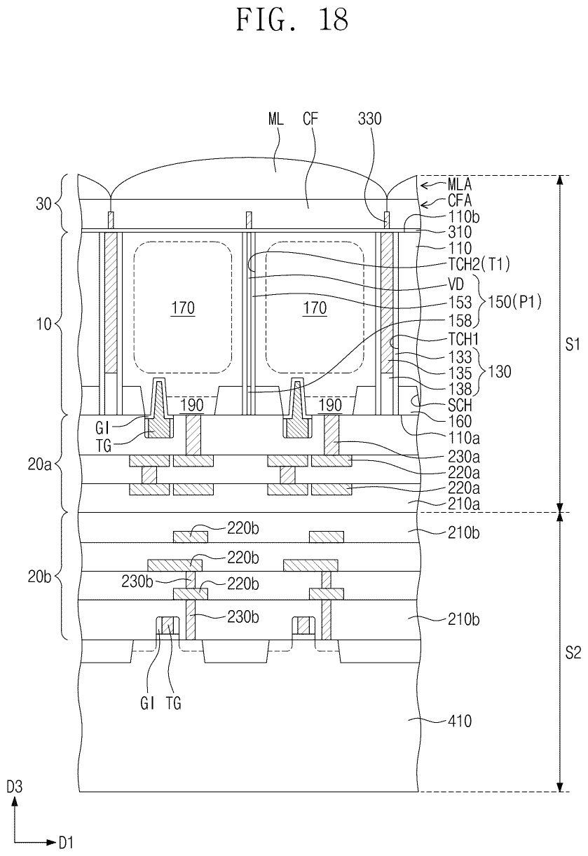

FIG. 18 is a cross-sectional view showing an image sensor according to some example embodiments.

Referring to FIG. 18, an image sensor according to some example embodiments may include a first structure S1 and a second structure S2. The first structure S1 may be disposed on the second structure S2. The first structure S1 may include a light transmission layer 30, a photoelectric conversion layer 10, and a first circuit wiring layer 20a. The photoelectric conversion layer 10 may be disposed between the light transmission layer 30 and the first circuit wiring layer 20a.

The light transmission layer 30 may include the microlenses ML, the color filters CF, the grid pattern 330, and the upper insulating film 310 of, e.g., FIG. 4A or 4B. The photoelectric conversion layer 10 may include the photoelectric conversion areas 170, the substrate 110 (hereinafter referred to as a first substrate), the first deep trench isolation layer 130, the second deep trench isolation layer 150, the shallow trench isolation layer 160, the gate dielectric layer GI, the transfer gates TG, the floating diffusion regions 190, the gates and the source/drain areas of logic transistors (RX, SX, and DX of, e.g., FIG. 2) of, e.g., FIGS. 4A and 4B. The first circuit wiring layer 20a may include first interlayer insulating films 210a, first wirings 220a, and first contact plugs 230a. The first interlayer insulating films 210a, the first wirings 220a, and the first contact plugs 230a may correspond to the interlayer insulating films 210, the wirings 220, and the contact plugs 230 of, e.g., FIGS. 11 and 4B.

The second structure S2 may include a second substrate 410 and a second circuit wiring layer 20b on the second substrate 410. Peripheral circuit transistors may be formed on the second substrate 410. The second circuit wiring layer 20b may include second interlayer insulating films 210b, second wirings 220b, and second contact plugs 230b that cover the peripheral circuit transistors. The second wirings 220b and the second contact plugs 230b may be provided in the second interlayer insulating films 210b to electrically connected to the peripheral circuit transistors.

The second structure S2 may include various peripheral circuits (e.g., the row decoder 2, the row driver 3, the column decoder 4, the timing generator 5, the correlated double sampler 6, the analog-to-digital converter 7, the input/output buffer 8, and the autofocus circuit of, e.g., FIG. 1) to operate the pixels in the first structures S1. For example, the second wirings 220b, the second contact plugs 230b, and the peripheral circuit transistors may configure various peripheral circuits.

The second circuit wiring layer 20b may be disposed between the first circuit wiring layer 20a and the second substrate 410. The lowermost one of the first interlayer insulating films 210a may be bonded to the uppermost one of the second interlayer insulating films 210b. The first structure S1 may be electrically connected to the second structure S2 through through-electrodes (not shown) in an edge area of the first structure S1. Alternatively, in some example embodiments a first bonding pad (not shown) may be disposed in the lowermost first interlayer insulating film 210a, a second bonding pad (not shown) may be disposed in the uppermost second interlayer insulating film 210b, and the first bonding pad may be bonded to the second bonding pad. For example, the first structure S1 may be electrically connected to the second structure S2 through the first and second bonding pads. The first and second bonding pads may include copper (Cu).

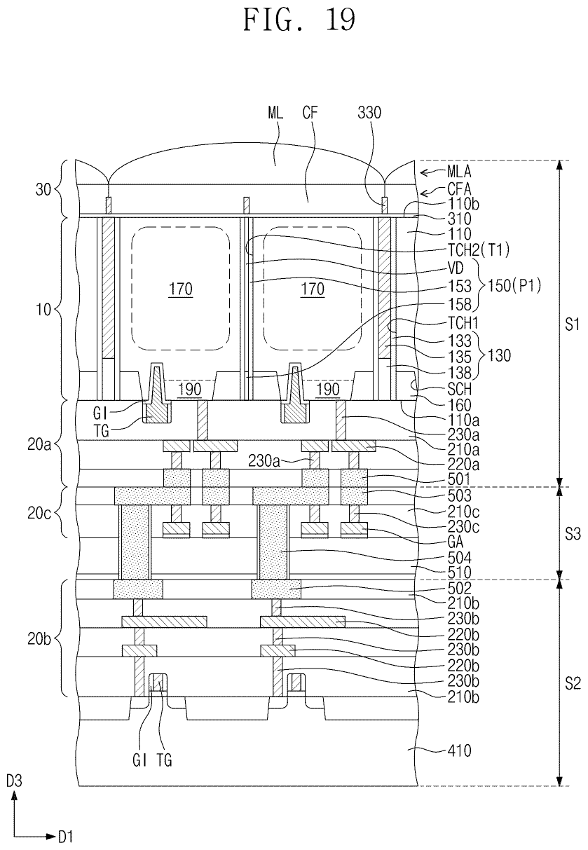

FIG. 19 is a cross-sectional view showing an image sensor according to some example embodiments.

Referring to FIG. 19, an image sensor according to some example embodiments may include a first structure S1, a second structure S2, and a third structure S3. The third structure S3 may be disposed between the first structure S1 and the second structure S2.

The first structure S1 may include a light transmission layer 30, a photoelectric conversion layer 10, and a first circuit wiring layer 20a. The light transmission layer 30 may be the same as the light transmission layer 30 of, e.g., FIG. 18. The photoelectric conversion layer 10 may include photoelectric conversion areas 170, a first substrate 110, a first deep trench isolation layer 130, a second deep trench isolation layer 150, a shallow trench isolation layer 160, a gate dielectric layer GI, transfer gates TG, and floating diffusion regions 190. The first circuit wiring layer 20a may include first interlayer insulating films 210a, first wirings 220a, first contact plugs 230a, and first bonding pads 501.

The second structure S2 may include a second substrate 410 and a second circuit wiring layer 20b on the second substrate 410. The second structure S2 may be the same or substantially the same as the second structure S2 of, e.g., FIG. 14. However, the second structure S2 may further include second bonding pads 502 provided in the uppermost one of the second interlayer insulating films 210b.

The third structure S3 may include a third substrate 510, gates GA on the third substrate 510, and a third circuit wiring layer 20c provided on the third substrate 510. The third substrate 510 may be a semiconductor substrate. Each of the gates GA may be disposed on the third substrate 510 with a gate dielectric film interposed therebetween. Source/drain areas (not shown) may be provided on the third substrate 510 on both sides of each of the gates GA.

The third circuit wiring layer 20c may include third interlayer insulating films 210c, third contact plugs 230c, third bonding pads 503, and fourth bonding pad 504. Although not shown, in some example embodiments, the third circuit wiring layer 20c may further include third wirings, each of the third wirings may be electrically connected to a corresponding gate GA, a corresponding source/drain area, a corresponding third bonding pad 503, and/or a corresponding fourth bonding pad 504.

According to some example embodiments, the first structure S1 may include some components of the pixel PXL of, e.g., FIG. 2 and the third structure S3 may include other components of the pixel PXL of, e.g., FIG. 2. For example, the first structure S1 may include a photoelectric conversion element PD, a transfer transistor TX, and a floating diffusion region FD of the pixel PXL, and the third structure S3 may include logic transistors RX, SX, and DX of the pixel PXL.

In some example embodiments, the logic transistors RX, SX, and DX may be provided on the third substrate 510 under each of the pixel regions PXR. For example, the pixel formed in each of the pixel regions PXR may include all the pixel transistors. Alternatively, in some example embodiments, transistors on the third substrate may be disposed so that a pair of pixels formed in a pair of pixel regions PXR of a pixel region group PXR may share at least one of the logic transistors RX, SX, and DX.

According to some example embodiments, the first structure S1 and the third structure S3 may be bonded to each other by a copper-to-copper bonding method, and the third structure S3 and the second structure S2 may also be bonded to each other by the copper-to-copper bonding method. For example, the bonding pads 501, 502, 503, and 504 of the first, second, and third structures S1, S2, and S3 may be formed of copper. The first bonding pad 501 of the first structure S1 may be bonded to the third bonding pad 503 of the third structure S3, and the second bonding pad 502 of the second structure S2 may be bonded to the fourth bonding pad 504 of the third structure S3. In some example embodiments, the fourth bonding pad 504 may be bonded to the second bonding pad 502 by passing through the third substrate 510.

Although the terms first, second, and the like may be used herein to describe various elements, components, steps and/or operations, these terms are only used to distinguish one element, component, step or operation from another element, component, step, or operation. Additionally, any or all of the elements described with reference to the figures may communicate with any or all other elements described with reference to the figures. For example, any element may engage in one-way and/or two-way and/or broadcast communication with any or all other elements in the figures, to transfer and/or exchange and/or receive information such as but not limited to data and/or commands, in a manner such as in a serial and/or parallel manner, via a bus such as a wireless and/or wired bus (not illustrated). The information may be encoded in various formats, such as in an analog format and/or in a digital format.

Although some example embodiments of the present inventive concepts have been described above, those skilled in the art or those having ordinary skill in the art will understand that various modifications and changes can be made to the example embodiments of the present inventive concepts without departing from the spirit and technical scope of the present inventive concepts as set forth in the claims described below.

Therefore, the technical scope of the present inventive concepts should not be limited to the example embodiments described in the detailed description of the specification, but should be determined by the patent claims.

According to some example embodiments of the present inventive concepts, a first deep trench isolation layer may be provided in the substrate to define a plurality of pixel region groups, and each of the pixel region groups may have a pair of pixel regions. A second deep trench isolation layer may be disposed between the pair of pixel regions, and a width of at least one portion (e.g., a first portion) of the second deep trench isolation layer may be smaller than a width of the first deep trench isolation layer. Therefore, in some example embodiments, a width of a buried conductive pattern in the at least one portion (e.g., the first portion) of the second deep trench isolation layer may be smaller than a width of a buried conductive pattern in the first deep trench isolation layer, or the at least one portion (e.g., the first portion) of the second deep trench isolation layer may not include the buried conductive pattern. As a result, in some example embodiments, when light is incident on the pair of pixel regions, light absorption by the second deep trench isolation layer can be reduced or minimized, thereby improving the photoelectric conversion efficiency of the image sensor.

According to some example embodiments of the present inventive concepts, microlenses may be respectively provided on the pixel region groups, and each of the microlenses may have a shape with a long axis and a short axis from a plan view (e.g., when viewed in a plan view). Therefore, in some example embodiments, a pair of pixels formed in the pair of pixel regions of each of the pixel region groups can perform an autofocus function. In other words, the autofocus function can be performed as needed, or alternatively desired anywhere in a pixel array. As a result, in some example embodiments, the degree of freedom and/or efficiency of the autofocus function of the image sensor can be improved.

What is claimed is:

1. An image sensor, comprising:
a substrate including a first surface and a second surface opposite to the first surface;
a first deep trench isolation layer in the substrate, the first deep trench isolation layer defining pixel region groups, each of the pixel region groups including a pair of pixel regions;
a second deep trench isolation layer between the pair of pixel regions of each of the pixel region groups;
photoelectric conversion areas in each of the pixel regions; and
a lens array on the second surface of the substrate and composed of two-dimensionally arranged microlenses,
each of the microlenses of the lens array having a shape, in plan view, with a long axis and a short axis, the short axis being substantially perpendicular to the long axis and shorter than the long axis,
the microlenses covering each of the pixel region groups, and
a width of at least a first portion of the second deep trench isolation layer being smaller than a width of the first deep trench isolation layer.

2. The image sensor of claim 1, wherein
the pixel regions of each of the pixel region groups are arranged in a direction parallel to the long axis of a microlens corresponding to each of the pixel region groups,
each of the pixel regions has a first width in the direction parallel to the long axis and a second width in a direction parallel to the short axis, and
the second width is less than twice the first width.

3. The image sensor of claim 2, wherein
the first width is 80% to 120% of the second width.

4. The image sensor of claim 1, wherein
the first deep trench isolation layer includes a first buried conductive pattern and a first insulating liner, the first insulating liner being between the first buried conductive pattern and the substrate,
the second deep trench isolation layer includes a second buried conductive pattern and a second insulating liner, the second insulating liner being between the second buried conductive pattern and the substrate, and
a first width of the second buried conductive pattern of at least the first portion of the second deep trench isolation layer is smaller than a width of the first buried conductive pattern of the first deep trench isolation layer.

5. The image sensor of claim 4, wherein
a second width of the second buried conductive pattern of a second portion of the second deep trench isolation layer is substantially same as the width of the first buried conductive pattern of the first deep trench isolation layer.

6. The image sensor of claim 4, wherein
a second width of the second buried conductive pattern of a second portion of the second deep trench isolation layer is greater than the first width of the second buried conductive pattern of at least the first portion of the second deep trench isolation layer, and
the second width of the second buried conductive pattern of the second portion of the second deep trench isolation layer is smaller than the width of the first buried conductive pattern of the first deep trench isolation layer.

7. The image sensor of claim 4, wherein
the first buried conductive pattern and the second buried conductive pattern include at least one of doped polysilicon or a metal.

8. The image sensor of claim 1, wherein
at least the first portion of the second deep trench isolation layer includes an insulating material and does not include a conductive material.

9. The image sensor of claim 1, wherein
the width of at least the first portion of the second deep trench isolation layer is 40% to 80% of the width of the first deep trench isolation layer.

10. The image sensor of claim 1, wherein,
from the plan view, a length of at least the first portion of the second deep trench isolation layer is 10% or more of a total length of the second deep trench isolation layer.

11. The image sensor of claim 1, wherein
the long axes of the microlenses are parallel to each other.

12. The image sensor of claim 1, wherein
at least one of the long axes of the microlenses are substantially perpendicular to at least another one of the long axes of the microlenses.

13. The image sensor of claim 12, further comprising
a color filter array between the second surface of the substrate and the lens array, the color filter array including a plurality of color filters, a color of a color filter under at least one of the microlenses differing from a color of a color filter under at least another one of the microlenses.

14. The image sensor of claim 13, wherein
each of the color filters covers a pair of pixel region groups adjacent to each other, and
the pixel regions of the pair of pixel region groups are arranged in a 2×2 matrix.

15. The image sensor of claim 13, wherein
each of the color filters covers eight pixel region groups adjacent to each other, and
the pixel regions of the eight pixel region groups are arranged in a 4×4 matrix.

16. An image sensor, comprising:
a substrate including a first surface and a second surface opposite to the first surface;
a first deep trench isolation layer in the substrate, the first deep trench isolation layer defining pixel region groups, each of the pixel region groups including a pair of pixel regions;
a second deep trench isolation layer between the pair of pixel regions of each of the pixel region groups;
photoelectric conversion areas in each of the pixel regions; and
a lens array on the second surface of the substrate and composed of two-dimensionally arranged microlenses,
each of the microlenses of the lens array having a shape, in plan view, with a long axis and a short axis, the short axis being substantially perpendicular to the long axis and shorter than the long axis,
the microlenses covering each of the pixel region groups,
the pixel regions of each of the pixel region groups being arranged in a direction parallel to the long axis of a microlens corresponding to each of the pixel region groups,
each of the pixel regions having a first width in the direction parallel to the long axis and a second width in a direction parallel to the short axis,
the first width being 80% to 120% of the second width, and
a width of at least a first portion of the second deep trench isolation layer being smaller than a width of the first deep trench isolation layer.

17. The image sensor of claim 16, wherein
the first deep trench isolation layer includes a first buried conductive pattern, and the second deep trench isolation layer includes a second buried conductive pattern, and
a first width of the second buried conductive pattern of at least the first portion of the second deep trench isolation layer is smaller than a width of the first buried conductive pattern of the first deep trench isolation layer.

18. The image sensor of claim 16, wherein
at least the first portion of the second deep trench isolation layer includes an insulating material and does not include a conductive material.

19. An image sensor, comprising:
a substrate including a first surface and a second surface opposite to the first surface;
a first deep trench isolation layer in the substrate, the first deep trench isolation layer defining pixel region groups, each of the pixel region groups including a pair of pixel regions;
a second deep trench isolation layer between the pair of pixel regions;
photoelectric conversion areas in each of the pixel regions; and
a lens array on the second surface of the substrate and composed of two-dimensionally arranged microlenses,
each of the microlenses of the lens array having a shape, in plan view, with a long axis and a short axis, the short axis being substantially perpendicular to the long axis and shorter than the long axis,
the microlenses covering each of the pixel region groups,
in the plan view, the second deep trench isolation layer including first and second portions that are spaced apart from each other in a direction parallel to the short axis of the microlenses, and
the pair of pixel regions connected to each other without an interface between the first portion and the second portion of the second deep trench isolation layer.

20. The image sensor of claim 19, wherein
the pixel regions of each of the pixel region groups are arranged in a direction parallel to the long axis of a microlens corresponding to each of the pixel region groups,
each of the pixel regions has a first width in the direction parallel to the long axis and a second width in the direction parallel to the short axis, and
the second width is less than twice the first width.
